(19) United States
(12) Patent Application Publication
(10) Pub. No.: US 2025/0343531 A1
(43) Pub. Date: Nov. 6, 2025

(54) ISOLATION CIRCUIT WITH MULTIPLEXER

(71) Applicant: TEXAS INSTRUMENTS INCORPORATED, Dallas, TX (US)

(72) Inventors: Giacomo Calabrese, Freising (DE); Asif Qaiyum, Freising (DE); Stefan Herzer, Marzling (DE)

(21) Appl. No.: 18/653,786

(22) Filed: May 2, 2024

(51) Int. Cl. H03H 11/04; H03K 17/00

(52) U.S. Cl. CPC H03H 11/04; H03K 17/002

(57) ABSTRACT

An apparatus comprising a first switch coupled between a first power terminal and a first inverter terminal, the first switch having a first switch control input. A second switch is coupled between the first inverter terminal and a second power terminal, the second switch having a second switch control input. A third switch is coupled between the second power terminal and a second inverter terminal, the third switch having a third switch control input. A fourth switch is coupled between the second inverter terminal and a reference terminal, the fourth switch having a fourth switch control input. An inverter circuit is coupled between first and second inverter terminals, the inverter circuit having outputs coupled to primary side terminals.

### BACKGROUND

Isolation is often desirable for interconnecting electrical systems to exchange data or power between the systems. For example, two circuits may be powered by different supply sources that do not share a common ground connection. The two circuits may be electrically isolated to prevent current and voltages in one system from negatively impacting the other system, for instance by damaging or interfering with the operation of one or more components of the other system. One example circuitry to provide data and power isolation is a transformer including a primary side coil and a secondary side coil that are electrically isolated from each other, but the primary side coil can transmit power and data signal to the secondary side coil, and vice versa, via magnetic coupling between the coils. One example system including a transformer is an isolated DC-DC converter. Other examples of isolation circuitry include capacitors and piezoelectric devices.

The properties of the isolation circuitry can affect various performance metrics of a system, such as the overall power efficiency of the system. For example, in a case where the isolation circuitry includes a transformer, the transformer efficiency can affect the overall power efficiency of the system. Transformer efficiency is a function of qualify factor (Q) and coupling coefficient (k). Larger inductor coils and/or more coil turns for a transformer can lead to a lower Q and a higher k, and a larger transformer footprint. Smaller inductor coils and/or fewer coil turns for a transformer can lead to a higher Q and a lower k, as well as a smaller transformer footprint. Also, a transformer with larger inductor coils and/or more coil turns may require a larger input voltage and provide a larger output voltage than a transformer with smaller inductor coils and/or fewer coil turns. The system may include transistors that operate at a higher voltage to interface with a transformer with larger inductor coils and/or more coil turns, but such transistors have higher on resistances (RDS-ON), which can reduce the overall power efficiency of the system.

### SUMMARY

Described is an apparatus comprising a first switch coupled between a first power terminal and a first inverter terminal, the first switch having a first switch control input. In at least one example, the apparatus comprises a second switch coupled between the first inverter terminal and a second power terminal, the second switch having a second switch control input. In at least example, the apparatus comprises a third switch coupled between the second power terminal and a second inverter terminal, the third switch having a third switch control input. In at least one example, the apparatus comprises a fourth switch coupled between the second inverter terminal and a reference terminal, the fourth switch having a fourth switch control input. In at least one example, the apparatus comprises an inverter circuit coupled between first and second inverter terminals, the inverter circuit having outputs coupled to primary side terminals.

Described is an apparatus comprising a first switch coupled between a first power terminal and a first rectifier terminal, the first switch having a first switch control input. In at least one example, the apparatus comprises a second switch coupled between the first rectifier terminal and a second power terminal, the second switch having a second switch control input. In at least one example, the apparatus comprises a third switch coupled between the second power terminal and a second rectifier terminal, the third switch having a third switch control input. In at least one example, the apparatus comprises a fourth switch coupled between the second rectifier terminal and a reference terminal, the fourth switch having a fourth switch control input. In at least one example, the apparatus comprises a rectifier circuit coupled between the first and second rectifier terminals, the rectifier circuit having inputs coupled to secondary side terminals.

Described is an apparatus comprising a first multiplexer circuit having a first selection input and a second selection input, the first multiplexer circuit configured to connect between a first power terminal and a first inverter terminal or between a second power terminal and the first inverter terminal responsive to a state of the first selection input. In at least one example, the first multiplexer circuit is configured to connect between the second power terminal and a second inverter terminal or between a first reference terminal and the second inverter terminal responsive to a state of the second selection input. In at least one example, the apparatus comprises an inverter circuit coupled between the first and second inverter terminals. In at least one example, the apparatus comprises a first control circuit having outputs coupled to the first and second selection inputs; a rectifier circuit coupled between first and second rectifier terminals. In at least one example, the apparatus comprises a second multiplexer circuit having a third selection input and fourth selection input, the third multiplexer circuit configured to connect between a third power terminal and the first rectifier terminal or between a fourth power terminal and the first rectifier terminal responsive to a state of the third selection input. In at least one example, the second multiplexer circuit is configured to connect between the fourth power terminal and the second rectifier terminal or between a second reference terminal and the second rectifier terminal responsive to a state of the fourth selection input. In at least one example, the apparatus comprises a second control circuit having outputs coupled to the third and fourth selection inputs. In at least one example, the apparatus comprises a transformer having a primary side winding and a secondary side winding, the primary side winding coupled to outputs of the inverter circuit, and the secondary side winding coupled to inputs of the rectifier circuit.

Described is a method comprising, in a first mode, enabling first and third switches and disabling second and fourth switches to connect first and second inverter terminals to, respectively, a first power terminal and a second power terminal. In at least one example, the method comprises, in a second mode, enabling the second and fourth switches and disabling the first and third switches to connect the first and second inverter terminals to, respectively, the second power terminal and the reference terminal. In at least one example, the method comprises alternating between the first and second modes.

Described is a packaged integrated circuit comprising a first semiconductor die, a second semiconductor die, and a transformer coupled to the first semiconductor die and the second semiconductor die. In at least one example, the first semiconductor die comprises a full bridge inverter coupled to a first power supply terminal and a second power supply terminal, wherein the first power supply terminal has a voltage level lower than a voltage level of the second power supply terminal. In at least one example, the first semiconductor die comprises a power multiplexer to selectively couple a third power supply terminal to the first power supply terminal and a fourth power supply terminal to the second power supply terminal in a first operation mode, and couple the fourth power supply terminal to first power supply terminal and a fifth power supply terminal to the second power supply terminal in a second operation mode.

Described is a packaged integrated circuit comprising a first semiconductor die, a second semiconductor die, and a transformer coupled to the first semiconductor die and the second semiconductor die. In at least one example, the first semiconductor die comprises a full bridge inverter to operate with a first set of power supply terminals in a first operation mode, and with a second set of power supply terminals in a second operation mode. In at least one example, the first semiconductor die comprises a power multiplexer to selectively couple a third set of power supply terminals to the first set of power supply terminals in the first operation mode, and a fourth set of power supply terminals to the second set of power supply terminals in the second operation mode.

### BRIEF DESCRIPTION OF THE DRAWINGS

The examples will be understood more fully from the detailed description given below and from the accompanying drawings, which, however, should not be taken to limit the disclosure to the specific examples, but are for explanation and understanding only.

FIG. 1 is a schematic depicting an example packaged integrated circuit (IC) having two semiconductor dies and an integrated isolation circuit comprising a power transformer and one or more data transformers, in accordance with at least one example.

FIG. 2 is a schematic depicting an example packaged IC having four semiconductor dies and an integrated isolation circuit comprising a power transformer and one or more data transformers, in accordance with at least one example.

FIGS. 3A-B are schematics of first and second transformers, respectively, where the first transformer has more turns than the second transformer, in accordance with at least some examples.

FIGS. 4A, 4B, 4C, and 4D is a schematic of a DC-DC converter with primary side and second side power supply multiplexers, in accordance with at least one example.

FIGS. 5A-B are schematics illustrating examples of operations of the DC-DC converter of FIG. 4A.

FIGS. 6A-B are schematics illustrating examples of operations of the DC-DC converter of FIG. 4A.

FIG. 7 and FIG. 8 are schematics illustrating example components of the DC-DC converter of FIG. 4A.

FIG. 9A is a plot illustrating voltage on a second capacitor between a secondary power supply terminal and ground during operation modes of FIGS. 5A-B, in accordance with at least one example.

FIG. 9B is a plot illustrating voltages on first and second output supply terminals during operation modes of FIGS. 6A-B, in accordance with at least one example.

FIG. 10 is a schematic of another example of the DC-DC converter of FIG. 4A.

FIG. 11 is a schematic of another example of the DC-DC converter of FIG. 4A.

FIG. 12 is a flowchart of a method of operating the primary side power multiplexer at a primary side of the DC-DC converter, in accordance with at least one example.

FIG. 13 is a flowchart of a method of operating the secondary side power multiplexer at a secondary side of the DC-DC converter, in accordance with at least one example.

### DETAILED DESCRIPTION OF EXAMPLE EMBODIMENTS

Described here is a system, such as a DC-DC converter, that has a first multiplexer coupled between the inputs of a primary side full bridge inverter and a set of primary side power rails including a first primary side power rail, a second primary side power rail, and a third primary side power rail. The first, second, and third primary side power rails can provide, respectively, first, second, and third voltages, with the second voltage between the first and third voltages. In some examples, the first voltage can be provided by an external power supply, the second voltage can be provided by a capacitor, and the third voltage can be a ground voltage. The primary side of the system may include a local feedback loop to regulate the second voltage at a target value by controlling the first multiplexer.

In some examples, the system also includes a second multiplexer coupled between the outputs of a secondary side full bridge rectifier and a set of secondary side power rails including a first secondary side power rail, a second secondary side power rail, and a third secondary side power rail. The system is configured to provide a fourth voltage, a fifth voltage, and a sixth voltage at, respectively, the first, second, and third secondary side power rails, with the fifth voltage between the fourth voltage and the sixth voltage. The secondary side of the system may also include a local feedback loop to regulate the third voltage at a target value by controlling the second multiplexer.

A first isolation circuitry, such as a transformer, a pair of capacitors, a pair of piezoelectric devices, etc., can be coupled between the outputs of the primary side full bridge inverter and the inputs of the secondary side full bridge rectifier, to transfer a signal (e.g., a power signal) from the primary side to the secondary side. The system may also include an outer feedback loop to regulate the fourth voltage by controlling the primary side full bridge inverter. The outer feedback loop may include a second isolation circuitry, such as a transformer, a pair of capacitors, a pair of piezoelectric devices, etc., to transmit data signal representing the fourth voltage from the secondary side to a controller on the primary side via the second isolation circuitry.

In a first primary side operation mode, the first multiplexer can connect the first and second input power rails (and provide the first and second voltages) to the inputs of the primary side full bridge inverter. In a second primary side operation mode, the first multiplexer can connect the second and third input power rails (and provide the second and third voltages) to the inputs of the primary side full bridge inverter. Also, in a first secondary side operation mode, the second multiplexer can connect the outputs of the secondary side full bridge rectifier to the first and second output power rails to provide a fourth voltage and a fifth voltage at, respectively, the first and second output power rails. Further, in a second secondary side operation mode, the second multiplexer can connect the outputs of the secondary side full bridge rectifier to the second and third output power rails to provide the fifth voltage and the sixth voltage at, respectively, the second and third output power rails.

Such arrangements can provide various advantages. Specifically, such arrangements provide a reduced voltage (e.g., a difference between the first and second voltages, a difference between the second and the third voltages) to across the inputs of the primary side full bridge inverter from the external power supply (which supplies the first voltage). Such arrangements also provide a reduced voltage (e.g., a difference between the fourth and fifth voltages, a difference between the fifth and sixth voltages) across the outputs of the secondary side full bridge rectifier. Because of the reduced voltages, the first and second multiplexers, the full bridge inverter, and the full bridge rectifier can be implemented with transistors that have a lower voltage stress limit but also lower RDS_ON, which can reduce power loss and improve the efficiency of each of the multiplexers, the inverter, and the rectifier. Also, a reduced voltage is applied across the primary side and the secondary side of the isolation circuitry. In a case where the isolation circuitry is a transformer, the reduced voltage allows a transformer with smaller inductor coils and/or fewer coil turns to be used, which can reduce the transformer footprint and the overall size of the system.

In the drawings, like reference numerals refer to like elements throughout, and the various features are not necessarily drawn to scale. Here, the same reference numbers or other reference designators are used in the drawings to designate the same or similar (either by function and/or structure) features.

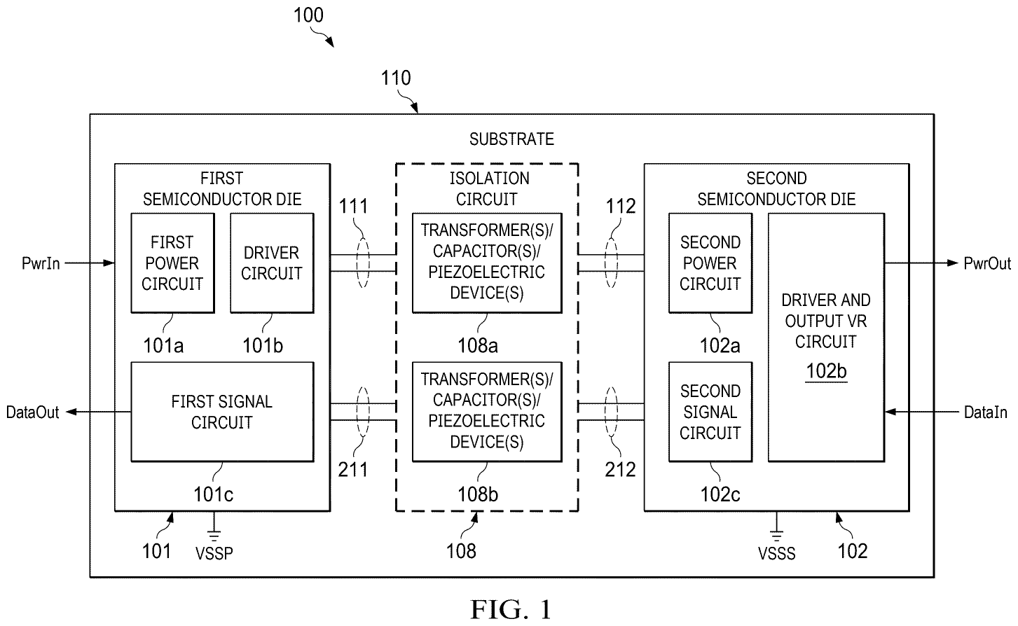

FIG. 1 is a schematic depicting an example packaged integrated circuit (IC) having two semiconductor dies and an integrated isolation circuit comprising a power transformer and one or more data transformers, in accordance with at least one example.

In at least one example, packaged IC 100 includes a first semiconductor die 101, and a second semiconductor die 102, an integrated isolation circuit 108, and a substrate 110 (e.g., package substrate), such as a lead frame. Semiconductor dies 101 and 102 are mounted to substrate 110, which can support first and second semiconductor dies 101 and 102 as a circuit support structure.

In at least one example, integrated isolation circuit 108 is integrated, formed, or embedded into layers (not shown) of substrate 110, as indicated by dashed lines. In at least one example, substrate 110 includes contact pads (not shown) and may include metallic interconnects 111, 112, 211, and 212 to allow interconnectivity between first and second semiconductor dies 101 and 102 and integrated isolation circuit 108. Each interconnect 111, 112, 211, and 212 may represent power and/or data channels with one or more electrical traces and/or vias.

In at least one example, packaged IC 100 can include a direct current (DC)-to-DC converter, and integrated isolation circuit 108 may provide a galvanic isolation barrier between two different power domains. Integrated isolation circuit 108 can include one or more transformers, one or more capacitors, or one or more piezoelectric devices. In at least one example, the DC-to-DC converter comprises circuits in first semiconductor die 101 and second semiconductor die 102 coupled via integrated isolation circuit 108a of integrated isolation circuit 108. Accordingly, first semiconductor die 101 may include circuits, such as a first power circuit 101a (e.g., half-bridge inverter or a full bridge inverter) and a driver circuit 101b, for providing a voltage and a current from a source to a primary side of integrated isolation circuit 108a (e.g., a primary side winding of a transformer, first terminals of capacitors/piezoelectric devices, etc.). In at least one example, the voltage and the current are provided from a power supply for a printed circuit board (PCB) on which substrate 110 is mounted. The PCB may be used to power a device such as a motor or a computing device.

In at least one example, second semiconductor die 102 may include a bridge circuit 102a (e.g., a half-bridge rectifier or a full bridge rectifier) and a driver and regulation circuit 102b for receiving a voltage and a current from a secondary side of integrated isolation circuit 108a and providing one or more regulated output voltages and/or currents for use by a load on the PCB. The load may be an application-specific integrated circuit (ASIC), a field-programmable gate array (FPGA), a microcontroller, a processor, etc. In at least one example, second semiconductor die 102 includes a second signal circuit 102c, which monitors a voltage on one of the power supply terminals in second semiconductor die 102 and provides a control for first signal circuit 101c via integrated isolation circuit 108b. In at least one example, first and second semiconductor dies 101 and/or 102 may represent controller circuit, current and voltage sensors, gate drivers for insulated-gate bipolar transistors, gate drivers for field effect transistors (FETs), etc.

In at least one example, first semiconductor die 101 and second semiconductor die 102 include first and second signals circuits 101c and 102c, respectively, that are coupled via isolation circuit 108b, which is also part of integrated isolation circuit 108. In at least one example, first and second signals circuits 101c and 102c provide bidirectional signaling via interconnects 211 and 212, respectively. In at least one example, interconnects 211 and 212 form one or more data channels and include full duplex communication buses.

In at least one example, first and second signals circuits 101c and 102c are used for sending and receiving signals between the first and second semiconductor dies 101 and 102 to realize a DC-DC converter. In at least one example, first and second signal circuits 101c and 102c can be used for other functions such as telemetry, data signaling, buffering of analog input signals for an analog-to-digital converter, buffering of digital input signals for a digital-to-analog converter, etc. In at least one example, first signal circuit 101c may receive control signal and/or clock to control switching activity of first power circuit 101a and/or driver circuit 101b. In at least one example, isolation circuit 108b can be multiplexed between sending internal data (e.g., feedback data from a secondary side back to a primary side within packaged IC 100) and external data (e.g., external to packaged IC 100).

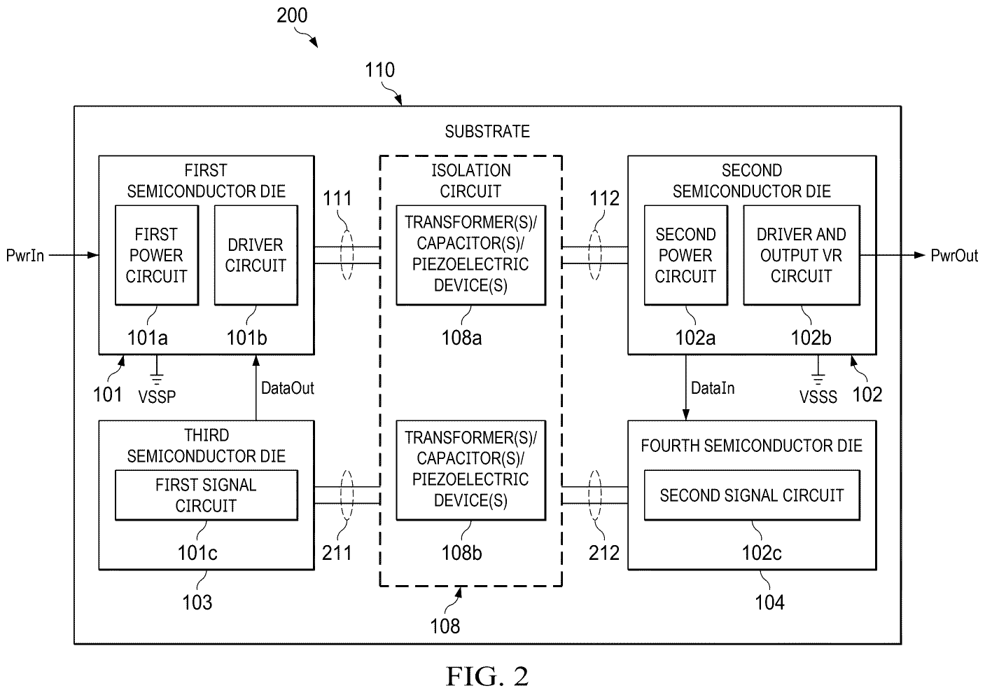

FIG. 2 is a schematic depicting an example packaged IC 200 having four semiconductor dies and an integrated isolation circuit comprising a power transformer and one or more data transformers, in accordance with at least one example. Functionally, packaged IC 200 is like packaged IC 100. In at least one example, first signal circuit 101c and second signal circuit 102c are implemented in their respective semiconductor dies. For instance, first signal circuit 101c is implemented in a third semiconductor die 103 and second signal circuit 102c is implemented in a fourth semiconductor die 104. In at least one example, third semiconductor die 103 and fourth semiconductor die 104 are flip-chip dies. In at least one example, third semiconductor die 103 and fourth semiconductor die 104 are a wire-bonded assembly. In some examples, packaged IC 100 and 200 may include additional semiconductor dies that are flip-chip dies or in a wired-bonded assembly.

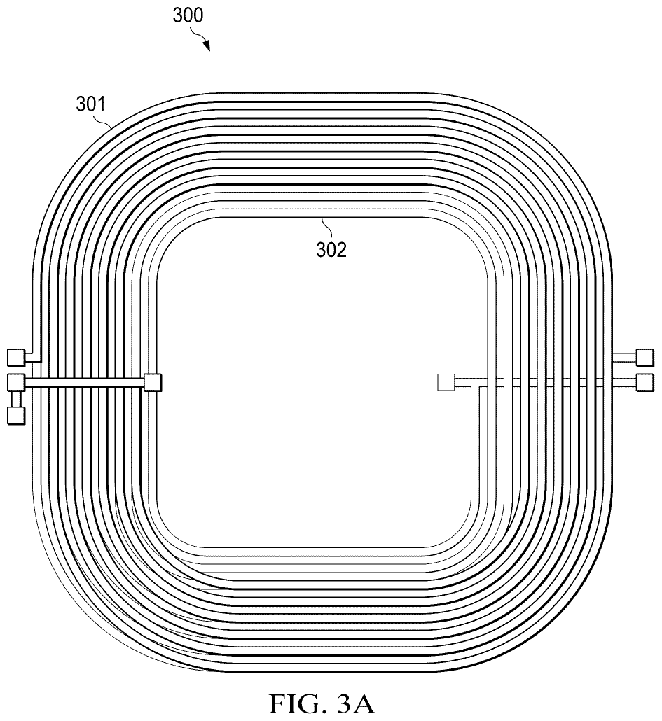

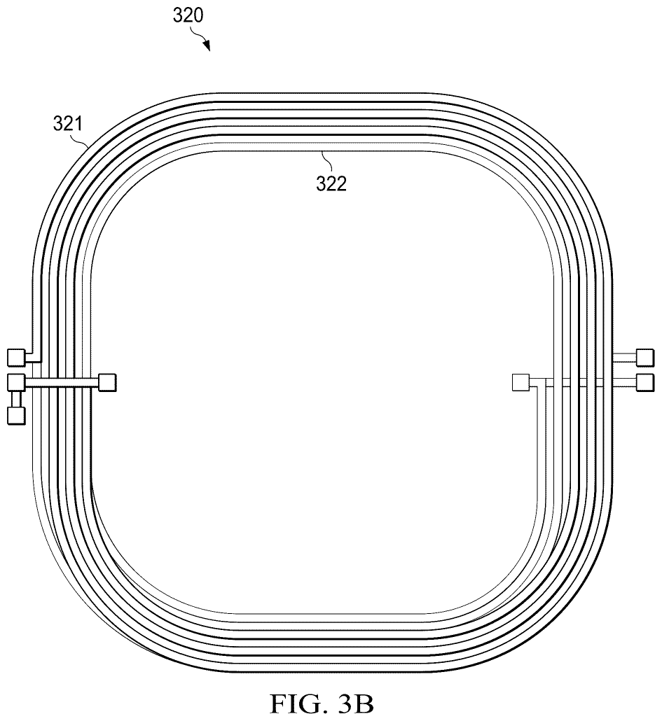

FIGS. 3A-B are schematics of first and second transformers 300 and 320, respectively, where first transformer 300 has more turns than second transformer 320, in accordance with at least some examples. One or more of first and second transformers 300 and 320 can be part of isolation circuit 108. Here, first transformer 300 includes a primary side winding 301 in a first metal layer of substrate 110 and a secondary side winding 302 in a second metal layer of substrate 110. In at least one example, the first and second metal layers are embedded in an isolation barrier material within substrate 110. In at least one example, the second metal layer is under or below the first metal layer. Second transformer 320 includes a primary side winding 321 in the first metal layer of substrate 110 and a secondary side winding 322 in the second metal layer of substrate 110. Primary side winding 301 and secondary side winding 302 of first transformer 300 have larger winding or coils and more turns than primary side winding 321 and secondary side winding 322 of second transformer 320, respectively. As such, first transformer 300 has lower Q and higher k while second transformer 320 has higher Q and lower k for similar transformer efficiency. In at least one example, second transformer 320 can be used with a DC-DC converter where transistors can tolerate a lower voltage difference between their terminals (e.g., source and gate terminals, drain and gate terminals). These transistors, being smaller in size than higher voltage rated transistors, have better figure of merit with respect to RDS-ON and Q, and can provide improved efficiency. Also, second transformer 320 has a smaller footprint, which allows for reduction in overall area of DC-DC converter plus transformer and improvement in bandwidth.

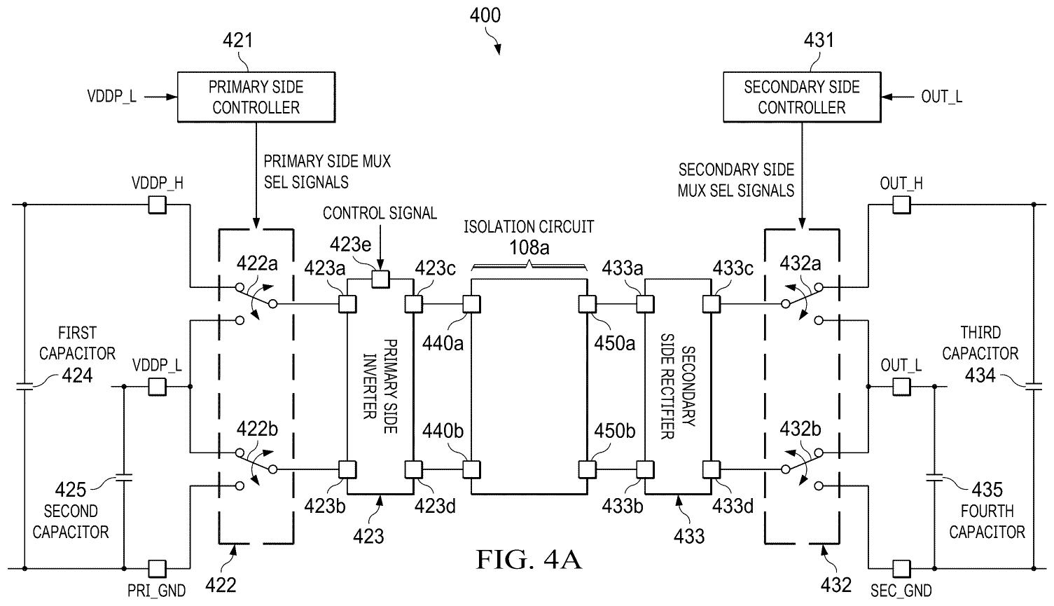

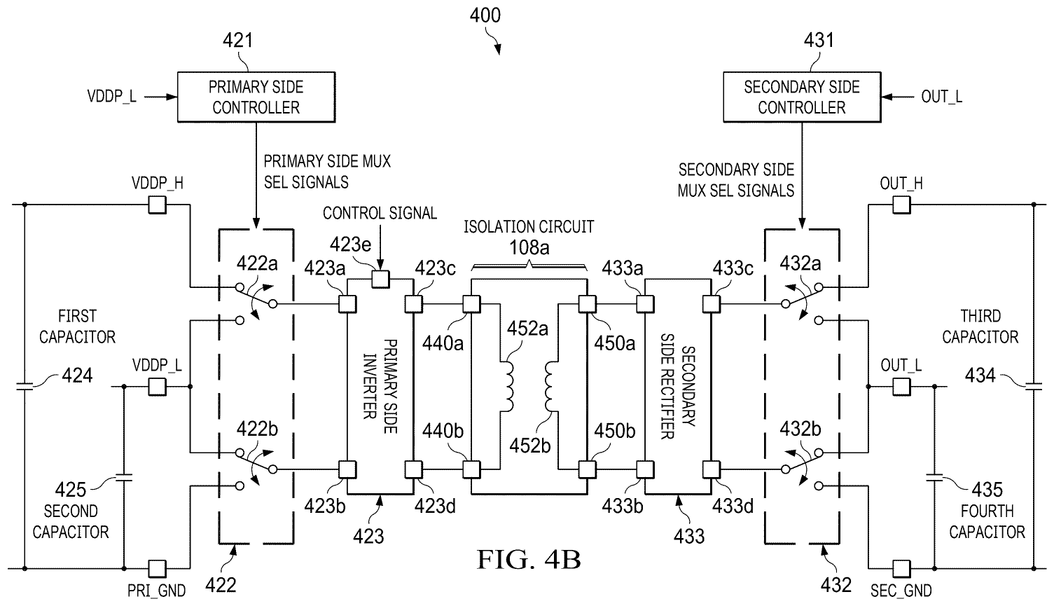

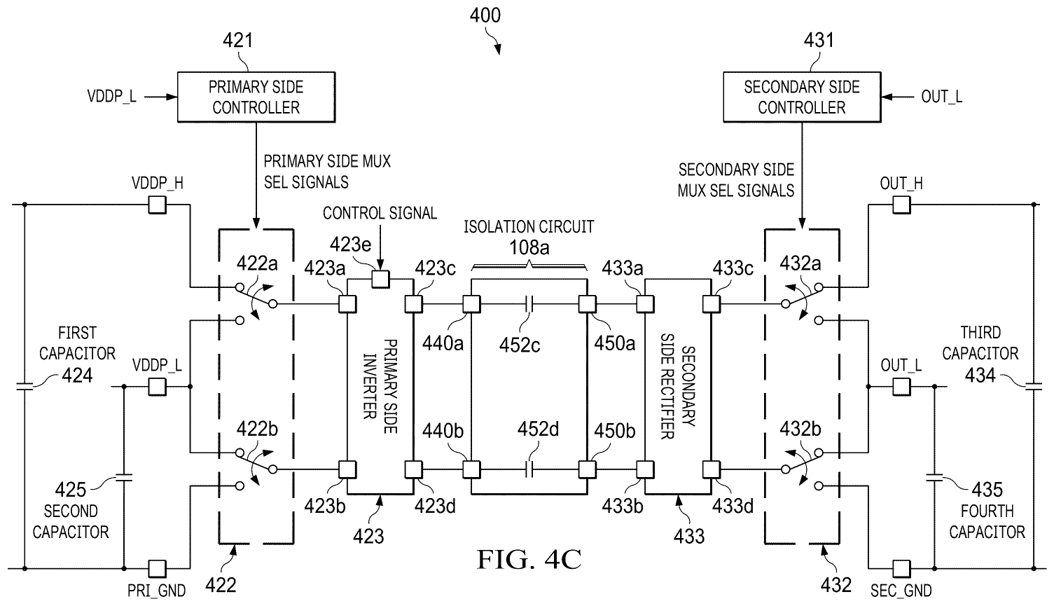

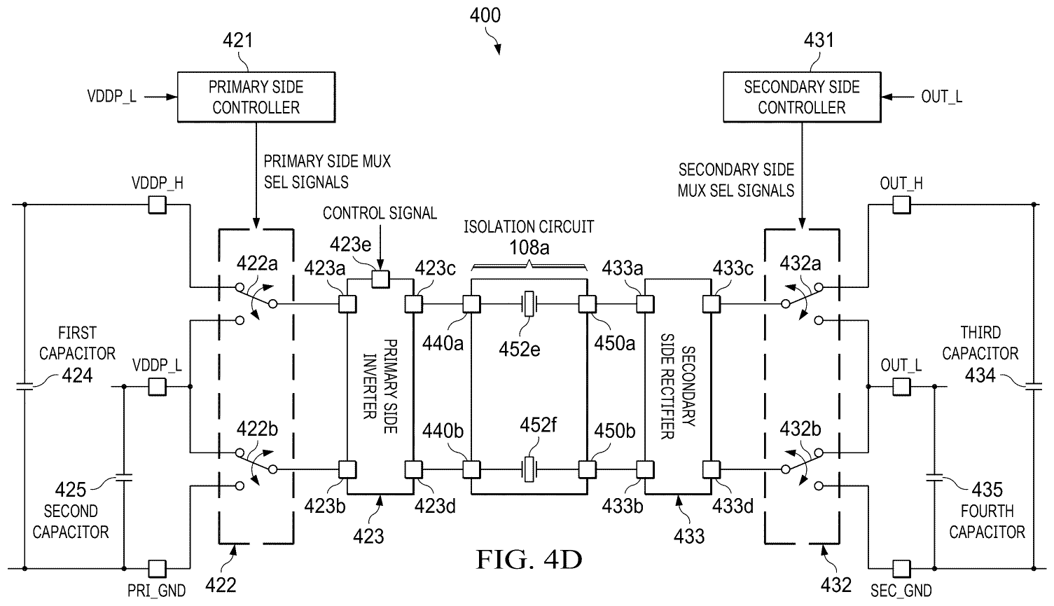

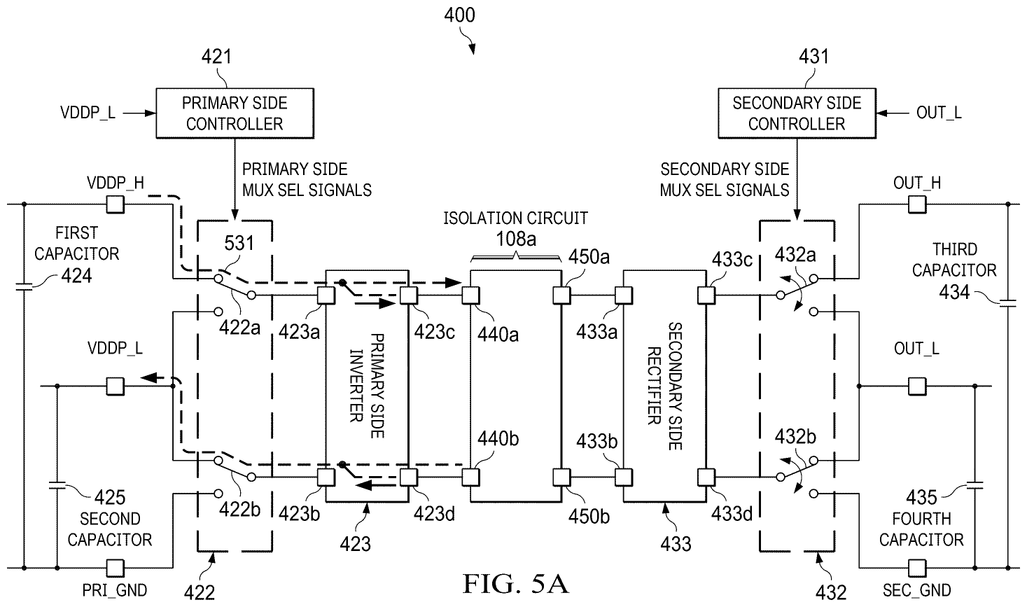

FIG. 4A is a schematic of a DC-DC converter 400 with primary side and secondary side power supply multiplexers, in accordance with at least one example. DC-DC converter 400 can be part of packaged IC 200 of FIG. 2. In at least one example, DC-DC converter 400 comprises a primary side controller 421, a first multiplexer 422, a primary side inverter 423, a first capacitor 424, a second capacitor 425, isolation circuit 108a, a secondary side controller 431, a second multiplexer 432, a secondary side rectifier 433, a third capacitor 434, and a fourth capacitor 435. Primary side inverter 423 has input power terminals 423a and 423b, output power terminals 423c and 423d, and a control input 423e. Power output terminals 423c and 423d are coupled to primary side terminals 440a and 440b of isolation circuit 108a. Control input 423e can receive a control signal (e.g., a switching signal) that causes primary side inverter 423 to switch and transfer power to the secondary side. Secondary side inverter 423 has input power terminals (or rectifier terminals) 433a and 433b and output power terminals 433c and 433d. Input power terminals 433a and 433b are coupled to secondary side terminals 450a and 450b of isolation circuit 108a.

First multiplexer 422 is coupled between a set of primary side power rails/terminals, including VDDP_H, VDDP_L, and PRI_GND, where PRI_GND can be a primary side ground/reference, and primary side terminals 440a and 440b of isolation circuit 108a. Second multiplexer 432 is coupled between secondary side terminals 450a and 450b of isolation circuit 108a and a set of secondary side power rails/terminals, including OUT_H, OUT_L, and SEC_GND, where SEC_GND can be a secondary side ground/reference.

In some examples, as shown in FIG. 4B, isolation circuit 108a can include a transformer including a primary side coil 452a coupled between primary side terminals 440a and 440b and a secondary side coil 452b coupled between secondary side terminals 450a and 450b. In some examples, as shown in FIG. 4C, isolation circuit 108a can include a first capacitor 452c coupled between primary side terminal 440a and secondary side terminal 450a, and a second capacitor 452d coupled between primary side terminal 440b and secondary side terminal 450b. In some examples, as shown in FIG. 4D, isolation circuit 108a can also include a first piezoelectric device 452e coupled between primary side terminal 440a and secondary side terminal 450a, and a second piezoelectric device 452f coupled between primary side terminal 440b and secondary side terminal 450b. Other isolation circuits 108 can also include a transformer, a pair of capacitors, or a pair of piezoelectric devices.

Referring back to FIG. 4A, in at least one example, first capacitor 424 is coupled between primary side power rails VDDP_H and PRI_GND. In at least one example, second capacitor 425 is coupled between primary side power terminals VDDP_L and PRI GND. In at least one example, third capacitor 434 is coupled between secondary side power terminals OUT_H and SEC GND. In at least one example, fourth capacitor 435 is coupled between secondary side power terminals OUT Land SEC_GND. In at least one example, a voltage (e.g., 3.3V) on the VDDP_H is higher than a voltage (e.g., 1.65V) on the VDDP_L. In at least one example, a voltage (e.g., 3.6V) on the OUT_H is higher than a voltage (e.g., 1.8V) on the low output power supply terminal OUT L. In at least one example, the voltage on the VDDP_L is substantially half of the voltage on the VDDP_H. In at least one example, the voltage on the OUT_L is substantially half of the voltage on the OUT_H. The voltage levels on the VDDP_L and the OUT_L can depend on applications and transistor voltage stress rating.

In at least one example, first multiplexer 422 comprises a first switch 422a and a second switch 422b. In at least one example, primary side controller 421 generates control signal(s) for first multiplexer 422 and these control signal(s) control operation of switches 422a and 422b. In at least one example, first switch 422a is operable to connect one of the VDDP_H or VDDP_L to input power terminal (or inverter terminal) 423a of primary side inverter 423 according to logic level of control signal(s) from primary side controller 421. In at least one example, second switch 422b is operable to connect one of the VDDP_L or PRI_GND to input power terminal (or inverter terminal) 423b of primary side inverter 423 according to logic level of control signal(s) from primary side controller 421. In at least one example, based on logic level of control signal(s) from primary side controller 421, primary side inverter 423 receives a high and low (or ground) power supply that maintains a voltage difference (e.g., 3.3V-1.65V, or 1.65V-0V) for the transistors of primary side inverter 423 below a threshold, to reduce voltage stress across transistors of primary side inverter 423 and first multiplexer 422. This allows use of low voltage transistors for primary side inverter 423 and in first multiplexer 422, and use of a smaller transformer for isolation circuit 108a.

In at least one example, second multiplexer 432 comprises a first switch 432a and a second switch 432b. In at least one example, secondary side controller 431 generates control signal(s) for second multiplexer 432 and these control signal(s) control operation of first and second switches 432a and 432b, respectively. In at least one example, first switch 432a is operable to connect the output power terminal 433c of secondary side rectifier 433 to one of the OUT H or the OUT_L according to logic level of control signal(s) from secondary side controller 431. In at least one example, second switch 432b is operable to connect the output power terminal 433d of secondary side rectifier 433 to one of the OUT_L or SEC_GND according to logic level of control signal(s) from secondary side controller 431. In at least one example, based on logic level of control signal(s) from secondary side controller 431, secondary side rectifier 433 receives a high and low (or ground) power supply that maintains a voltage difference (e.g., 3.6V-1.8V, or 1.8V-0V) for the transistors of secondary side rectifier 433 to reduce voltage stress across transistors of secondary side rectifier 433 and second multiplexer 432. This allows use of low voltage transistors for secondary side rectifier 433 and second multiplexer 432, and use of a smaller transformer for isolation circuit 108a.

In at least one example, primary side control signal(s) from primary side controller 421 cause first multiplexer 422 to selectively connect the high VDDP_H and low VDDP_L input power supply terminals to input power terminals 423a and 423b of primary side inverter 423. In at least one example, secondary side control signal(s) from secondary side controller 431 cause second multiplexer 432 to selectively connect the high OUT_H and low OUT_L output power supply terminals to output power terminals 433c and 433d of secondary side rectifier 433.

In at least one example, first multiplexer 422 can connect VDDP_H and VDDP_L to input power terminals 423a/b in a first operation mode (e.g., a first primary side operation mode) and connect VDDP_L and PRI_GND to primary side power terminals 423a/b in a second operation mode (e.g., a second primary side operation mode). The primary side inverter 423 switches in both the first and second operation modes to perform power transfer to the secondary side. In some examples, the VDDP_L voltage can be regulated using a first hysteretic feedback loop implemented by primary side controller 421 which senses the voltage at the VDDP_L. Primary side controller 421 can cause first multiplexer 422 to operate in the first operation mode until the voltage at VDDP_L exceeds a first threshold voltage, and then switch to the second operation mode when primary side inverter 423 stops switching. Also, primary side controller 421 can cause first multiplexer 422 to operate in the second operation mode until the voltage at VDDP_L falls below a second threshold voltage, and then switch back to the first operation mode, with the first/second threshold voltages being different to provide hysteresis. The first hysteretic feedback loop can regulate the voltage at VDDP_L to control the voltage difference across transistors of first multiplexer 422 and primary side inverter 423 to reduce voltage stress applied to the transistors. The first hysteretic feedback loop can cause first multiplexer 422 to switch between the first and second operation modes based on different threshold voltages to reduce switching caused by voltage ripples at VDDP_L. In some examples, primary side controller 421 can include a comparator with built-in hysteresis to compare VDDP_L with a first reference, where the first and second threshold voltages are plus/minus certain percentage (e.g., 10%) of the first reference.

In some examples, primary side controller 421 can cause first multiplexer 422 to alternate between the first operation mode and the second operation mode repeatedly, and adjust the relative duration of the first operation mode and the second operation mode based on comparing the voltage at VDDP_L against the first and second threshold voltages. For example, if the voltage at VDDP_L exceeds the first threshold voltage, primary side controller 421 can reduce the duration of the first operation mode relative to the duration of the second operation mode. If the voltage at VDDP_L falls below the second threshold voltage, primary side controller 421 can reduce the duration of the second operation mode relative to the duration of the first operation mode.

In at least one example, second multiplexer 422 can connect output power terminals 433c and 433d of secondary side rectifier 433 to, respectively, OUT_H and OUT_L in a third operation mode (e.g., a first secondary side operation mode), and output power terminals 433c and 433d to, respectively, OUT_L and SEC_GND in a fourth operation mode (e.g., a second secondary side operation mode). In some examples, the OUT_L voltage can be regulated using a second hysteretic feedback loop implemented by secondary side controller 431 which senses the voltage at the OUT_L. In some examples, secondary side controller 421 can cause second multiplexer 432 to operate in the third operation mode until the voltage at OUT_L falls below a third threshold voltage, and then switch to the fourth operation mode. Also, secondary side controller 431 can cause second multiplexer 432 to operate in the fourth operation mode until the voltage at OUT_L exceeds a fourth threshold voltage, and then switch back to the third operation mode, with the third/fourth threshold voltages being different to provide hysteresis. In some examples, secondary side controller 431 can include a comparator with built-in hysteresis to compare OUT_L with a second reference, where the third and fourth threshold voltages are plus/minus certain percentage (e.g., 10%) of the second reference.

The second hysteretic feedback loop can regulate the voltage at OUT_L to control the voltage difference across transistors of second multiplexer 432 and secondary side rectifier 433 to reduce voltage stress applied to the transistors, and to provide OUTL as a regulated voltage supply via OUT L to loads connected to OUT L. The second hysteretic feedback loop can switch between the first and second operation modes based on different threshold voltages to reduce switching caused by voltage ripples at OUT_L.

In some examples, secondary side controller 421 can also cause second multiplexer 432 to alternate between the third and fourth operation modes repeatedly at a particular duty cycle depending on the load conditions on OUT_H and OUT_L. For example, secondary side controller 421 can cause second multiplexer 432 to switch between the third and fourth operation modes at 50% duty cycle to reduce net charge flow out of the fourth capacitor 435 via OUT_L, and adjust the duty cycle (and the relative durations of the third and fourth operation modes) based on comparing the voltage at OUT_L with the third and fourth voltages. For example, if the voltage at OUT L falls below the third threshold voltage, secondary side controller 431 can reduce the duration of the third operation mode relative to the duration of the fourth operation mode. If the voltage at OUT_L exceeds the fourth threshold voltage, secondary side controller 431 can reduce the duration of the fourth operation mode relative to the duration of the third operation mode.

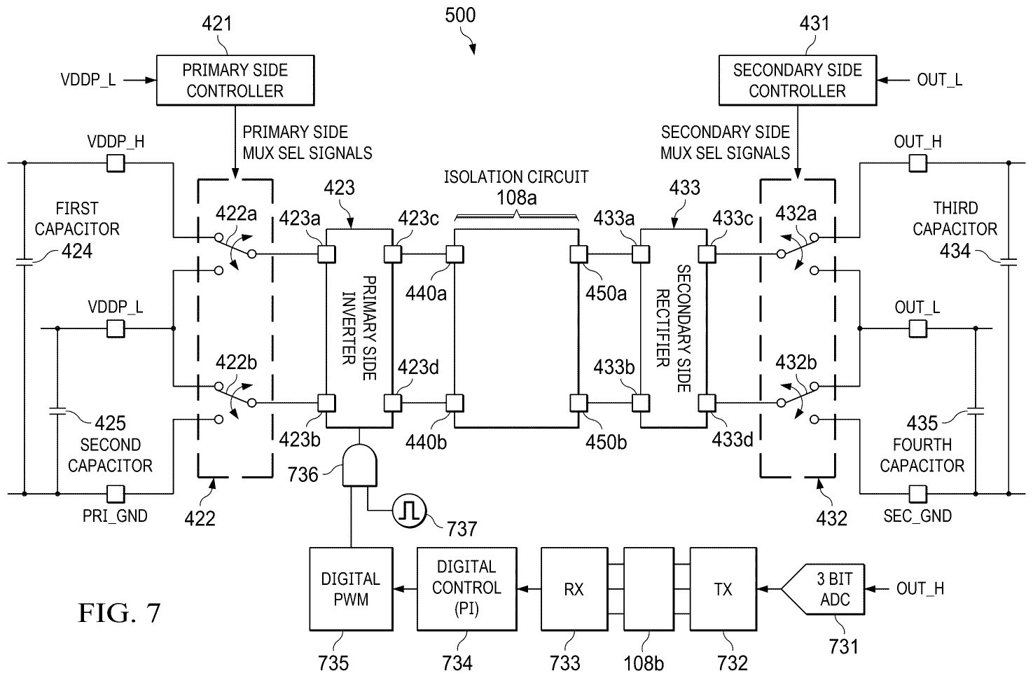

In at least one example, a third feedback loop is provided (described in FIG. 7), which monitors a voltage on the OUT_H to control the switching operation of primary side inverter 423. In at least one example, a fourth feedback loop is provided, which monitors a voltage on the high input power supply terminal VDDP_H to modulate the switching operation of second multiplexer 432 and/or the second hysteretic feedback loop operation.

In at least one example, voltages on primary side power terminals (VDDP_H and VDDP_L) are maintained by first capacitor 424 and second capacitor 425, respectively. In at least one example, voltages on the secondary side power terminals (OUT_H and OUT_L) are maintained by third capacitor 434 and fourth capacitor 435, respectively. In at least one example, first capacitor 424, second capacitor 425, third capacitor 434, and fourth capacitor 435 are located off package or off die. In at least one example, first capacitor 424, second capacitor 425, third capacitor 434, and fourth capacitor 435 are integrated within a package.

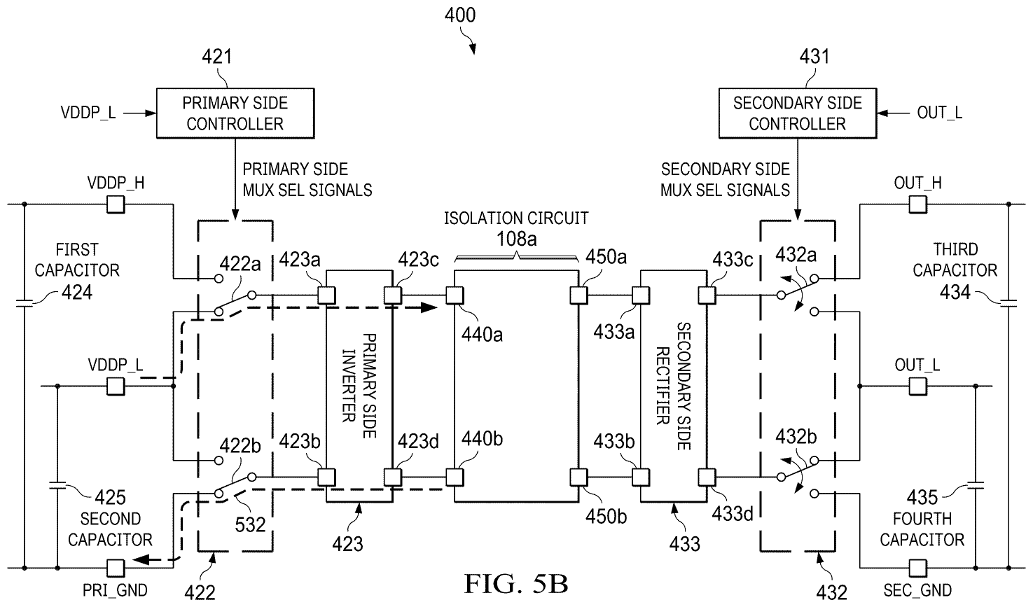

FIGS. 5A-B is a schematic illustrating example operations of DC-DC converter 400. FIG. 5A illustrates the first primary side operation mode where primary side controller 421 generates a control signal(s) to cause first switch 422a to connect the VDDP_H to input power terminal of 423a primary side inverter 423. In this example, the control signal(s) causes second switch 422b to connect the VDDP_L to input power terminal 423b of primary side inverter 423.

In at least one example, a current from the VDDP_H flows through primary side inverter 423 into primary side terminal 440a of isolation circuit 108a. Also, a current flows from primary side terminal 440b of isolation circuit 108a through primary side inverter 423 to the VDDP_L. The current flow is indicated by dotted path 531. The current charges second capacitor 425 and discharges first capacitor 424, causing the voltage at VDDP_L to increase.

In at least one example, in the first primary side operation mode, the first hysteretic feedback loop operation compares the voltage at VDDP_L with a first threshold voltage. If the voltage at VDDP_L is below the first threshold voltage, primary side controller 421 can cause first multiplexer 422 to remain in the first primary side operation mode, or maintain the duration of the first primary side operation mode in a case where primary side controller 421 repeatedly alternate between the first and second primary side operation modes. If the voltage at VDDP_L exceeds the first threshold voltage, primary side controller 421 can cause first multiplexer 422 to switch to the second primary side operation mode when primary side inverter 423 stops switching and the primary side does not transfer power to the secondary side, or shorten the duration of the first primary side operation mode in a case where primary side controller 421 repeatedly alternate between the first and second primary side operation modes.

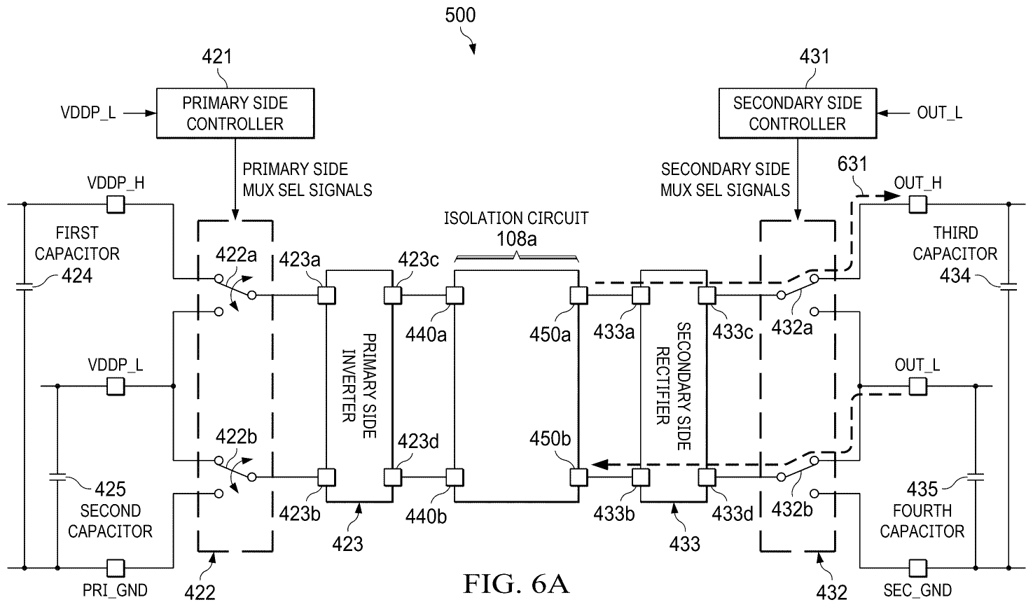

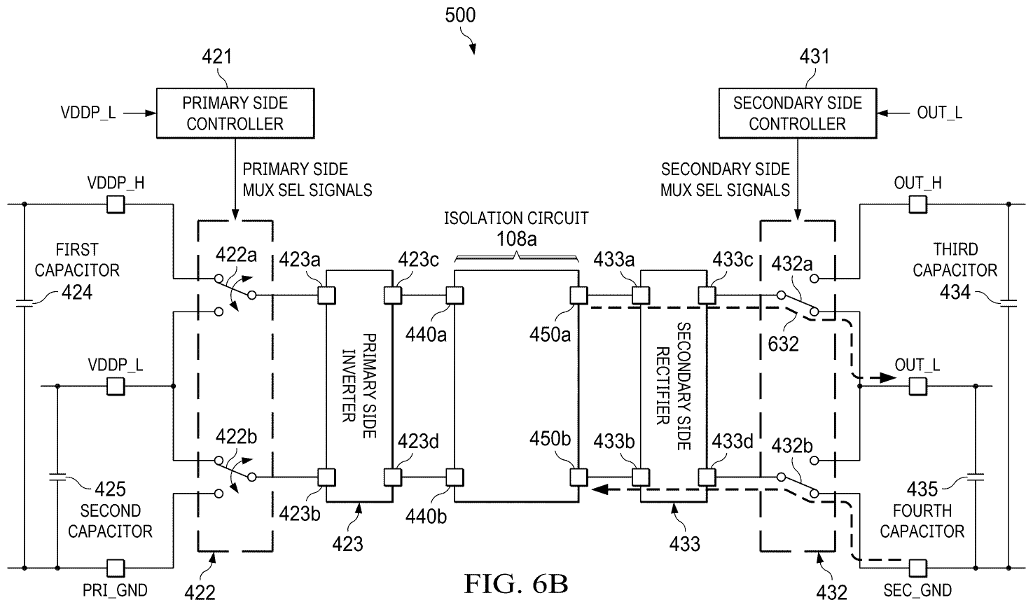

In FIG. 5A, during the first primary side operation mode (or first operation mode), secondary side controller 431 generates a control signal(s) to cause first switch 432a of second multiplexer 432 to operate in one of the first secondary side operation mode (or third operation mode) or the second secondary side operation mode (or fourth operation mode). In the first secondary side operation mode, as to be described in FIG. 6A, second multiplexer 432 connects output power terminal 433c of secondary side rectifier 433 to the OUT_H and connects output power terminal 433d of secondary side rectifier 433 to the OUT_L. In the second secondary side operation mode, as to be described in FIG. 6B.

FIG. 5B illustrates the second primary side operation mode where primary side controller 421 generates a control signal(s) to cause first switch 422a to connect VDDP_L to input power terminal 423a of primary side inverter 423 and second switch 422b to connect PRI_GND to input power terminal 423b of primary side inverter 423. In at least one example, a current from the VDDP_L flows through primary side inverter 423 into primary side terminal 423a of isolation circuit 108a, and current flows out of primary side terminal 423b of isolation circuit 108a through primary side inverter 423 into PRI_GND. The current flow is indicated by dotted path 532. The current discharges second capacitor 425, causing the voltage at VDDP_L to decrease.

In at least one example, in the second primary side operation mode, the first hysteretic feedback loop operation compares the voltage at VDDP_L with a second threshold voltage. If the voltage at VDDP_L is above the second threshold voltage, primary side controller 421 can cause first multiplexer 422 to remain in the second primary side operation mode, or maintain the duration of the second primary side operation mode in a case where primary side controller 421 repeatedly alternate between the first and second primary side operation modes. If the voltage at VDDP_L falls below the second threshold voltage, primary side controller 421 can cause first multiplexer 422 to switch back to the first primary side operation mode when primary side inverter 423 stops switching and the primary side does not transfer power to the secondary side, or shorten the duration of the second primary side operation mode in a case where primary side controller 421 repeatedly alternate between the first and second primary side operation modes.

In FIG. 5B, during the second primary side operation mode (or second operation mode), secondary side controller 431 generates a control signal(s) to cause first switch 432a of second multiplexer 432 to operate in one of the first secondary side operation mode (or third operation mode) or the second secondary side operation mode (or fourth operation mode). In the first secondary side operation mode, as to be described in FIG. 6A, second multiplexer 432 connects output power terminal 433c of secondary side rectifier 433 to the OUT_H and connects output power terminal 433d of secondary side rectifier 433 to the OUT_L. In the second secondary side operation mode, as to be described in FIG. 6B.

As discussed herein, a third feedback loop can provide a control signal, such as a pulse width modulated (PWM) signal, that determines the switching and non-switching windows of primary side inverter 423. During the non-switching windows, the first and second hysteretic feedback loop operations can also be enabled to control first and second multiplexers 422 and 432, respectively, to regulate the voltages at VDDP_L and OUT_L. For instance, the third feedback loop monitors the voltage on OUT_H to generate a PWM signal that determines the switching and non-switching window of primary side inverter 423 and when to enable and disable the switching activity of first multiplexer 422. In at least one example, the fourth feedback loop monitors the voltage on VDDP_H or VDDP_L to generate a PWM signal that determines when to enable and disable the switching activity of second multiplexer 432. In at least one example, the fourth operation loop uses the same PWM signal (e.g., one generated based on monitoring the OUT_H) and provides it to second multiplexer 432 to control the switching activity of second multiplexer 432 just as it does for first multiplexer 422.

FIGS. 6A-B is a schematic illustrating example operations of DC-DC converter 400 (herein DC-DC converter 500). FIG. 6A illustrates the first secondary side operation mode where secondary side controller 431 generates a control signal(s) to cause first switch 432a of second multiplexer 432 to connect the output power terminal 433c to the OUT_H, and cause second switch 432b of second multiplexer 432 to connect output power terminal 433d to the OUT L. In at least one example, the power transferred from the primary side causes a current to flow from output power terminal 433c to OUT_H and charge third capacitor 434. A return current flows from OUT_L into output power terminal 433d and discharge fourth capacitor 435, causing the voltage at OUTL to decrease. This current flow is indicated by identifier 631.

In at least one example, in the first secondary side operation mode (or third operation mode), the second hysteretic feedback loop operation compares the voltage at OUT_L with a third threshold voltage. If the voltage at OUT_L is above the third threshold voltage (e.g., due to additional load sinking current from OUT_L), secondary side controller 431 can cause second multiplexer 432 to remain in the first secondary side operation mode, or maintain the duration of the first secondary side operation mode in a case where secondary side controller 431 repeatedly alternate between the first and second secondary side operation modes (e.g., 50% duty cycle to have zero net current flowing in/out of OUT_L if no additional load). If the voltage at OUT_L exceeds the third threshold voltage, secondary side controller 431 can cause second multiplexer 432 to switch to the second secondary side operation mode if primary side inverter 423 is not switching, or shorten the duration of the first secondary side operation mode in a case where secondary side controller 431 repeatedly alternate between the first and second secondary side operation modes.

In FIG. 6A, during the first secondary side operation mode, primary side controller 421 generates a control signal(s) to cause first switch 422a and second switch 422b of first multiplexer 422 to operate as described in FIGS. 5A and 5B.

FIG. 6B illustrates the second secondary side operation mode where secondary side controller 431 generates a control signal(s) to cause first switch 432a of second multiplexer 432 to connect output power terminal 433c to the OUT_L, and second switch 432b of second multiplexer 432 to connect output power terminal 433d to the SEC_GND. In at least one example, the power transferred from the primary side causes a current to flow from output power terminal 433c to OUT L and charge the fourth capacitor 435, causing the voltage at OUTL to increase. A return current flows from the SEC_GND into output power terminal 433d. The current flow is indicated by dotted path 632. During the second secondary side operation mode, OUT_H is disconnected from secondary side rectifier 433 and isolation circuit 108a and does not receive power.

In at least one example, in the second secondary side operation mode (or fourth operation mode), the second hysteretic feedback loop operation compares the voltage at OUT_L with a fourth threshold voltage. If the voltage at OUT_L is below the fourth threshold voltage (e.g., due to additional load sinking current from OUT_L), secondary side controller 431 can cause second multiplexer 432 to remain in the second secondary side operation mode, or maintain the duration of the second secondary side operation mode in a case where secondary side controller 431 repeatedly alternate between the first and second secondary side operation modes (e.g., 50% duty cycle to have zero net current flowing in/out of OUT_L if no additional load). If the voltage at OUT L exceeds the fourth threshold voltage, secondary side controller 431 can cause second multiplexer 432 to stop the second secondary side operation mode if primary side inverter 423 is not switching, or shorten the duration of the second secondary side operation mode in a case where secondary side controller 431 repeatedly alternate between the first and second secondary side operation modes.

In FIG. 6B, during the first secondary side operation mode, primary side controller 421 generates a control signal(s) to cause first switch 422a and second switch 422b of first multiplexer 422 to operate as described in FIGS. 5A and 5B.

FIG. 7 is a schematic illustrating additional components of DC-DC converter 400 (herein DC-DC converter 500), including logic to control switching behavior of a primary side inverter of the DC-DC converter, in accordance with at least one example. In at least one example, switching activity of primary side inverter 423 is controlled by a data control signal(s) that is based on voltage level on the OUT_H. In at least one example, to maintain galvanic isolation, the voltage level on the OUT_H is processed and transmitted through isolation circuit 108b, which can include a transformer, a pair of capacitors, a pair of piezoelectric devices, similar to isolation circuit 108a, to the isolation between primary and secondary side circuitries.

In at least one example, the logic to control the switching behavior of primary side inverter 423 is part of the third feedback loop operation and comprises an analog-to-digital converter (ADC) 731 (e.g., a 3-bit ADC), a transmit circuit 732, isolation circuit 108b, a receive circuit 733, a digital control circuit 734 (e.g., a proportional-integrative (PI)), a digital pulse width modulation (PWM) circuit 735, and logic gate 736 (e.g., an AND or NAND gate). In at least one example, ADC 731 has an input coupled to the OUT_H. In at least one example, ADC 731 samples the voltage on the OUT_H at a sampling frequency (e.g., 512 KHz) and generates a digital representation of the voltage. The granularity of the digital representation of the voltage depends on the bit-size of ADC 731. While DC-DC converter 500 of FIG. 7 illustrates a 3-bit ADC for ADC 731, any bit-size ADC may be used based on a desired accuracy of controlling the switching activity of primary side inverter 423. In at least one example, the digital representation is provided as an output of ADC 731 for transmit circuit 732 to transmit to receive circuit 733 via isolation circuit 108b. In at least one example, isolation circuit 108b has a smaller footprint (e.g., having a smaller transformer) compared to isolation circuit 108a and provides isolation to data signal from second semiconductor die 102 to first semiconductor die 101.

In at least one example, receive circuit 733 detects the received digital representation, amplifies it, and provides it to digital control circuit 734. In at least one example, digital control circuit 734 generates a number of signal edges of the digital representation within a period of the sampling frequency (e.g., 512 KHz). In at least one example, the digital control output is used to generate pulses of varying widths by digital PWM circuit 735. In at least one example, an output of digital PWM circuit 735 is a PWM signal, which is logically AND-ed by logic gate 736 with a switching signal of higher frequency than the sampling frequency for ADC 731 (e.g., a clock operating at 90 MHz is AND-ed with the PWM signal). The resulting output of logic gate 736 is a pulse train with a logic high and a logic low pulse width. In at least one example, the switching signal of higher frequency is provided from a clock source 737, which may be external to DC-DC converter 500 of FIG. 7 (e.g., off-die or off-package). In at least one example, clock source 737 is on-die or on-package.

In at least one example, the duration of the pulse width determines an on-period of primary side inverter 423. For instance, the duration of the logic high pulse determines a period primary side inverter 423 switches and drives power signal to isolation circuit 108a. The duration of the logic low pulse determines a period in which primary side inverter 423 stops switching. In at least one example, during the logic high pulse from logic gate 736 when primary side inverter 423 is switching, first multiplexer 422 maintains the operation mode for its switches (e.g., first switch 422a and second switch 422b). In at least one example, during the logic low pulse from logic gate 736, when primary side inverter 423 is not switching, first multiplexer 422 executes the operation mode for its switches (e.g., first switch 422a and second switch 422b), which alternate between coupling the VDDP_H and the VDDP_L, and coupling the VDDP_L and the primary ground supply terminal PRI_GND.

In at least one example, the fourth feedback operation loop comprises another set control circuitries including an ADC (e.g., a 3-bit ADC), a transmit circuit, a data transformer, a receive circuit, a digital control circuit (e.g., a proportional-integrative (PI)), and a digital PWM circuit. In at least one example, the other set of control circuitries is a replica of ADC 731, transmit circuit 732, isolation circuit 108b, receive circuit 733, a digital control circuit 734 (e.g., a proportional-integrative (PI)), and digital PWM circuit 735 but flipped. For instance, the ADC has an input coupled to the VDDP_H, or the VDDP_L and converts the voltage on that terminal to a digital representation. The digital presentation is then transmitted by the transmit circuit 732 over another data transformer and received by a receive circuit. An output of the receive circuit is provided to a digital control circuit that performs the PI operation. The output of the digital circuit is received by a digital PWM circuit when generates the PWM modulated signals that are used to enable or disable the switching activity of second multiplexer 432. In at least one example, the fourth operation loop uses the same output from digital PWM circuit 735 and provides it to second multiplexer 432 to control the switching activity of second multiplexer 432 just as it does for first multiplexer 422. In one such example, the output from digital PWM circuit 735 is transmitted through a transmitter over another data transformer for use by second multiplexer 432.

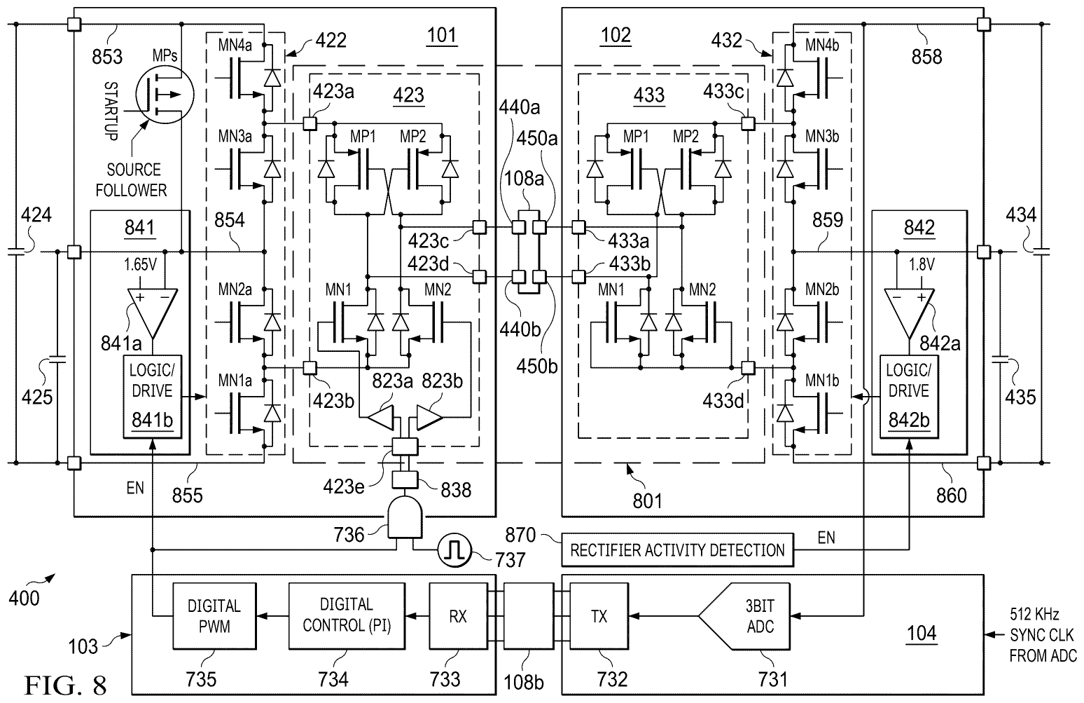

FIG. 8 is a schematic illustrating examples of internal components of DC-DC converter 400. In at least one example, DC-DC converter 400 can be a quasi-resonant converter comprising primary side inverter 423 and secondary side rectifier 433. Silicon parasitic capacitance of quasi-resonant converter 400 resonates with inductance terms of isolation circuit 108a to achieve zero voltage switching (ZVS) on primary side inverter 423 and ZVS and zero current switching (ZCS) on secondary side rectifier 433. The operation of primary side inverter 423 and secondary side rectifier 433 is described in U.S. Pat. No. 10,622,908 B2, which is incorporated by reference.

In at least one example, primary side inverter 423 (e.g., a full bridge inverter) comprises n-type transistors MN1 and MN2, p-type transistors MP1 And MP2, and drivers 823a and 823b. In at least one example, transistor MP1 has a source terminal couple to input power terminal 423a and a drain terminal coupled to a gate terminal of transistor MP2 and a drain terminal of transistor MN1. In at least one example, transistor MP2 has a source terminal coupled to input power terminal 423a and a drain terminal coupled to a gate terminal of transistor MP1 and a drain terminal of transistor MN2. In at least one example, transistor MN1 has a source terminal coupled to input power terminal 423b. In at least one example, transistor MN2 has a source terminal coupled to input power terminal 423b. In at least one example, the drain terminal of transistor MN2 is coupled to output power terminal 423c of primary side inverter 423 and primary side terminal 440a of isolation circuit 108a. In at least one example, the drain terminal of transistor MN1 is coupled to output power terminal 423d of primary side inverter 423 and primary side terminal 440b of isolation circuit 108a. In at least one example, a gate terminal of transistor MN1 is driven by a first driver 823a while a gate terminal of transistor MN2 is driven by a second driver 823b. In at least one example, first driver 823a and second driver 823b are driven according to pulse width from logic gate 736. In at least one example, DC-DC converter 400 includes an overlap detection circuit 838 that is coupled to an output of logic gate 736. In at least one example, overlap detection circuit 838 ensures that first driver 823a and second driver 823b do not turn on at the same time and there is a dead period between a turn-on time of first driver 823a and a turn-on time of second driver 823b. In at least one example, the dead period ensures that there is no short circuit current or unintended leakage through primary side inverter 423.

In at least one example, first multiplexer 422 comprises series coupled n-type transistors MN1a, MN2a, MN3a, and MN4a. In at least one example, a drain terminal of transistor MN4a is coupled to a power supply terminal 853 (e.g., VDDP_H). In at least one example, a source terminal of transistor MN4a is coupled to input power terminal 423a. In at least one example, a drain terminal of transistor MN3a is coupled to input power terminal 423a and a source terminal of transistor MN3a is coupled to a power supply terminal 854 (e.g., VDDP_L). In at least one example, a drain terminal of transistor MN2a is coupled to power supply terminal 854 and a source terminal of transistor MN2a is coupled to input power terminal 423b. In at least one example, a source terminal of transistor MN1a is coupled to a power supply terminal 855 (e.g., PRI_GND) and a drain terminal is coupled to input power terminal 423b. In at least one example, first switch 422a comprises transistors MN3a and MN4a. In at least one example, second switch 422b comprises transistors MN1a and MN2a.

In at least one example, transistors MN1a, MN2a, MN3a, and MN4a are controlled by the first hysteretic feedback loop operation, which is implemented by first voltage regulator (VR) 841. In at least one example, first VR 841 forms a local control loop to regulate voltage on power supply terminal 854 (VDDP_L). In at least one example, primary side controller 421 comprises first VR 841, receive circuit 733, digital control circuit 734 (e.g., PI), digital PWM circuit 735. In at least one example, ADC 731 and transmit circuit 732 are also part of primary side controller 421. In at least one example, first VR 841 comprises a comparator 841a and a logic circuit 841b, an output of which is used to control transistors MN1a, MN2a, MN3a, and MN4a. In at least one example, comparator 841a compares a voltage on power supply terminal 854 with a first reference and generates an output for logic circuit 841b to turn on or off transistors MN1a, MN2a, MN3a, and MN4a of first multiplexer 422 to regulate the voltage on power supply terminal 854. In some examples, comparator 841a can have built-in hysteresis (e.g., +/−10% around the first reference) when comparing the voltage with the first reference to implement the first hysteretic feedback loop.

In at least one example, the first reference is a voltage (e.g., 1.65V), which is a desired voltage on power supply terminal 854. In at least one example, the first reference is an adjustable reference. In at least one example, the first reference is adjustable by software, hardware, or a combination of them. In at least one example, the first reference is generated off die or off package. In at least one example, the first reference is generated on-die or on package. Any suitable circuit such as a voltage divider, bandgap circuit, etc., can be used to generate the first reference.

In at least one example, an output of logic circuit 841b is halted from changing according to output of digital PWM circuit 735. In at least one example, when first driver 823a and second driver 823b are switching (e.g., in a high pulse duration from digital PWM circuit 735), the output of logic circuit 841b is maintained and not allowed to change by the enable signal EN. In at least one example, when first driver 823a and second driver 823b are not switching (e.g., in a low pulse duration from digital PWM circuit 735), the output of logic circuit 841b is allowed to change, which turns on/off transistors MN1a, MN2a, MN3a, and MN4a to maintain voltage on power supply terminal 854 and to alternatively connect power supply terminal 853 (VDDP_H), power supply terminal 854 (VDDP_L), and/or power supply terminal 855 (PRI_GND) to input power terminals 423a and 423b of primary side inverter 423 as discussed herein.

In at least one example, the voltage on power supply terminal 854 (VDDP_L) is pre-charged by a source follower at startup. When voltages on power supply terminals ramp up at startup, they may take time to reach their steady state expected voltage levels, which may overstress the operation of first VR 841. To mitigate that stress and to reach the steady state faster, the source follower provides charge from first capacitor 424 to second capacitor 425 during startup. In at least one example, the source follower comprises a p-type transistor MPs controlled by a startup signal, where the p-type transistor MPs is coupled between power supply terminal 853 (VDDP_H) and power supply terminal 854 (VDDP_L). In at least one example, the source follower is turned on during startup of DC-DC converter 400 to charge second capacitor 425. In at least one example, the source follower can be replaced with a linear voltage regulator, which is turned on during startup to stabilize the voltage on power supply terminal 854 (VDDP_L) to its desired level. In at least one example, the source follower or the linear voltage regulator can be turned on to assist with recharging second capacitor 425 should there be a sudden or unexpected drop in charge in second capacitor 425, and which may take longer to replenish using the first hysteretic feedback loop operation.

In at least one example, n-type transistors MN1a, MN2a, MN3a, and MN4a of first multiplexer 422 are controlled by the output of logic circuit 841b such that when transistors MN4a and MN2a are on, transistors MN3a and MN1a are off, and when transistors MN3a and MN1a are on, transistors MN4a and MN2a are off. In at least one example, transistors MN4a and MN2a of first multiplexer 422 are replaced with p-type transistors. In at least one example, transistor MN4a is driven by a level-shifter to avoid short circuit current. In at least one example, transistors MN1a, MN2a, MN3a, and MN4a are driven by their respective level-shifters and drivers.

In at least one example, secondary side rectifier 433 (e.g., a full bridge rectifier) comprises n-type transistors MN1 and MN2 and p-type transistors MP1 And MP2. In at least one example, transistor MP1 has a source terminal coupled to output power terminal 433c and a drain terminal coupled to a gate terminal of transistor MP2 and a drain terminal of transistor MN1. In at least one example, transistor MP2 has a source terminal coupled to output power terminal 433c and a drain terminal coupled to a gate terminal of transistor MP1 and a drain terminal of transistor MN2. In at least one example, transistor MN1 has a source terminal coupled to output power terminal 433d. In at least one example, transistor MN2 has a source terminal coupled to output power terminal 433d. In at least one example, the drain terminal of transistor MN2 is coupled to a first terminal of the secondary winding of isolation circuit 108a. In at least one example, the drain terminal of transistor MN1 is coupled to a second terminal of the secondary winding of isolation circuit 108a. In at least one example, transistor MN1 and transistor MN2 are diode-connected.

In at least one example, the transistors of primary side inverter 423 (e.g., full bridge inverter) and secondary side rectifier 433 (e.g., full bridge rectifier) are complementary metal oxide semiconductor (CMOS) transistors. In at least one example, the CMOS transistors are low threshold voltage (LVT) transistors that are suited to operate at lower voltages and are faster than high threshold voltage (HVT) transistors. As such, quasi-resonant converter 801 can switch with lower losses and operate at higher frequencies and enable use of smaller inductance and area for isolation circuit 108a. The parasitic diodes between the source and drain terminals of the transistors of quasi-resonant converter 801 is not used (Vf of about 600 mV) while the LVT channel is used thus improving passive rectification (e.g., Vf of about 200 mV).

In at least one example, second multiplexer 432 comprises series coupled n-type transistors MN1b, MN2b, MN3b, and MN4b. In at least one example, a drain terminal of transistor MN4b is coupled to a power supply terminal 858 (e.g., OUT_H). In at least one example, a source terminal of transistor MN4b is coupled to output power terminal 433c. In at least one example, a drain terminal of transistor MN3b is coupled to output power terminal 433c and a source terminal of transistor MN3b is coupled to a power supply terminal 859 (e.g., OUT_L). In at least one example, a drain terminal of transistor MN2b is coupled to power supply terminal 859 and a source terminal of transistor MN2b is coupled to output power terminal 433d. In at least one example, a source terminal of transistor MN1b is coupled to a power supply terminal 860 (secondary side ground SEC_GND) and a drain terminal is coupled to output power terminal 433d. In at least one example, first switch 432a comprises transistors MN3b and MN4b. In at least one example, second switch 432b comprises transistors MN1b and MN2b.

In at least one example, transistors MN1b, MN2b, MN3b, and MN4b of second multiplexer 432 are controlled by the second hysteretic feedback loop operation, which is implemented by a second voltage regulator (VR) 842. In at least one example, second VR 842 forms a local control loop to regulate voltage on power supply terminal 859 (OUT_L). In at least one example, secondary side controller 431 comprises second VR 842. In at least one example, second VR 842 comprises a comparator 842a and a logic circuit 842b, an output of which is used to control transistors MN1b, MN2b, MN3b, and MN4b of second multiplexer 432. In at least one example, comparator 842a compares a voltage on power supply terminal 859 (OUT_L) with a second reference and generates an output for logic circuit 842b to turn on or off transistors MN1b, MN2b, MN3b, and MN4b of second multiplexer 432 to regulate the voltage on power supply terminal 859 and to alternatively connect power supply terminal 858 (OUT_H), power supply terminal 859 (OUT_L), and/or power supply terminal 860 (SEC_GND) to output power terminals 433c and 433d of secondary side rectifier 433 as discussed herein. In some examples, comparator 842a can have built-in hysteresis (e.g., +/−10% around the first reference) when comparing the voltage with the second reference to implement the second hysteretic feedback loop.

In at least one example, the second reference is a voltage (e.g., 1.8V), which is a desired voltage on power supply terminal 859. In at least one example, the second reference is an adjustable reference. In at least one example, the second reference is adjustable by software, hardware, or a combination of them. In at least one example, the second reference is generated off die or off package. In at least one example, the second reference is generated on-die or on package. Any suitable circuit such as a voltage divider, bandgap circuit, etc. can be used to generate the second reference.

In at least one example, second VR 842 operates independent of first VR 841. For instance, the first hysteretic feedback loop operation is independent of the second hysteretic feedback loop operation. In at least one example, second VR 842 operates to maintain charges on third capacitor 434 and/or fourth capacitor 435 by controlling first switch 432a and second switch 432b of second multiplexer 432.

In at least one example, a fourth operation loop (not shown) enables and disables the switching activity of second multiplexer 432 based on a voltage on power supply terminal 853 or a voltage on power supply terminal 854. In at least one example, the fourth operation loop uses the same output from digital PWM circuit 735 and provides it to second multiplexer 432 to control the switching activity of second multiplexer 432 just as it does for first multiplexer 422.

In at least one example, the voltage on power supply terminal 859 (OUT_L) is pre-charged by a source follower at startup. In at least one example, the source follower is coupled between power supply terminal 858 (OUT_H) and power supply terminal 859 (OUT_L). In at least one example, the source follower is turned on during startup of the DC-DC converter 400 to charge fourth capacitor 435. In at least one example, the source follower in second semiconductor die 102 is similar in structure and function as the source follower in first semiconductor die 101.

In at least one example, n-type transistors MN1b, MN2b, MN3b, and MN4b of second multiplexer 432 are controlled by the output of logic circuit 842b such that when transistors MN4b and MN2b are on, transistors MN3b and MN1b are off, and when transistors MN3b and MN1b are on, transistors MN4b and MN2b are off. In at least one example, transistors MN4b and MN2b of second multiplexer 432 are replaced with p-type transistors. In at least one example, transistor MN4b is driven by a level-shifter to avoid short circuit current. In at least one example, transistors MN1b, MN2b, MN3b, and MN4b are driven by their respective level-shifters and drivers.

In at least one example, voltage on power supply terminal 858 (OUT_H) is regulated by a third control loop, which starts with power supply terminal 858 (OUT_H) and includes ADC 731, transmit circuit 732, isolation circuit 108b, receive circuit 733, digital control circuit 734, digital PWM circuit 735, logic gate 736, overlap detection circuit 838, primary side inverter 423, isolation circuit 108a, secondary side rectifier 433, and second multiplexer 432. In at least one example, depending on loading conditions on power supply terminal 858 (OUT_H), the third control loop establishes the pulse width of the PWM signal from digital PWM circuit 735. For instance, if loading conditions increase and the voltage on power supply terminal 858 (OUT_H) starts to drop, the third control loop will cause wider high-time pulse width.

The third control loop also controls logic circuit 841b (by providing an EN signal), which in turn controls the switching operation of first multiplexer 422. Specifically, logic circuit 841b switches the operation mode of first multiplexer 422 during the low-time of the PWM signal from digital PWM circuit 735, when primary side inverter 423 is not switching and the primary side is not transferring power to the secondary side. Such arrangements can avoid disruption of the power transfer caused by the switching of first multiplexer 422.

In some examples, the secondary side of DC-DC converter 400 also includes a rectifier activity detection circuit 870 having inputs coupled to secondary side rectifier 433. Rectifier detection circuit can detect, at secondary side rectifier 433, the switching of primary side inverter 423 and power transfer from the primary side to the secondary side, and provide an EN signal to logic circuit 842b, which in turn controls the switching operation of second multiplexer 432. Specifically, logic circuit 842b switches the operation mode of second multiplexer 432 during when primary side inverter 423 stops switching and the primary side is not transferring power to the second side, to avoid disruption of the power transfer caused by the switching of second multiplexer 432. Rectifier activity detection circuit 870 can detect the switching (or non-switching) of primary side inverter 423 based on, for example, detecting diodes of the full bridge of secondary side rectifier 433 going into forward drop differentially, presence of switching at the secondary side rectifier 433, presence of current flow at the output power terminals 433c/433d of secondary side rectifier 433, etc.

As discussed herein, isolation circuit 108a provides isolation between primary side inverter 423 and secondary side rectifier 433. This isolation allows first and second multiplexer 422 and 432 to independently connect the power supply terminals without affecting the isolated power transfer. The first and second hysteretic feedback loop operations from local loops of first VR 841 and second VR 842 govern which power supply terminals are coupled to primary side inverter 423 and secondary side rectifier 433 and when, based on local voltage conditions of the power supply terminals.

In at least one example, first multiplexer 422 and second multiplexer 432 operate as voltage doubler and halver. First multiplexer 422 and second multiplexer 432 in-part regulate voltages on power supply terminal 854 (VDDP_L) and power supply terminal 859 (OUT_L), respectively, as voltages between the high input voltage and ground, and high output voltages and ground. For instance, voltages (in-between voltages) between power supply terminal 853 (VDDP_H) and power supply terminal 855 (PRI_GND) and between power supply terminal 858 (OUT_H) and power supply terminal 860 (SEC_GND), respectively. These in-between voltages can be used for circuits operating at lower supply voltages. In one example, dedicated low dropout (LDO) regulators are not needed to generate the in-between voltages. In at least one example, the switching operation of first multiplexer 422 and second multiplexer 432 is slower than quasi-resonant converter 801, and as such any potential electromagnetic interference (EMI) and transformer losses are mitigated. In one example, first multiplexer 422 and second multiplexer 432 operates at 512 KHz while quasi-resonant converter 801 operates at 90 MHz. Accordingly, with the described examples, the input and output voltages of a DC-DC converter can be extended (e.g., doubled) while reducing the voltage stresses on the transistors of the multiplexers, inverter, and rectifier, while addition low voltage power rails (e.g., OUT_L) can be provided in addition to the high voltage power rail (e.g., OUT_H) on the secondary side. All these can improve the utility of the DC-DC converter.

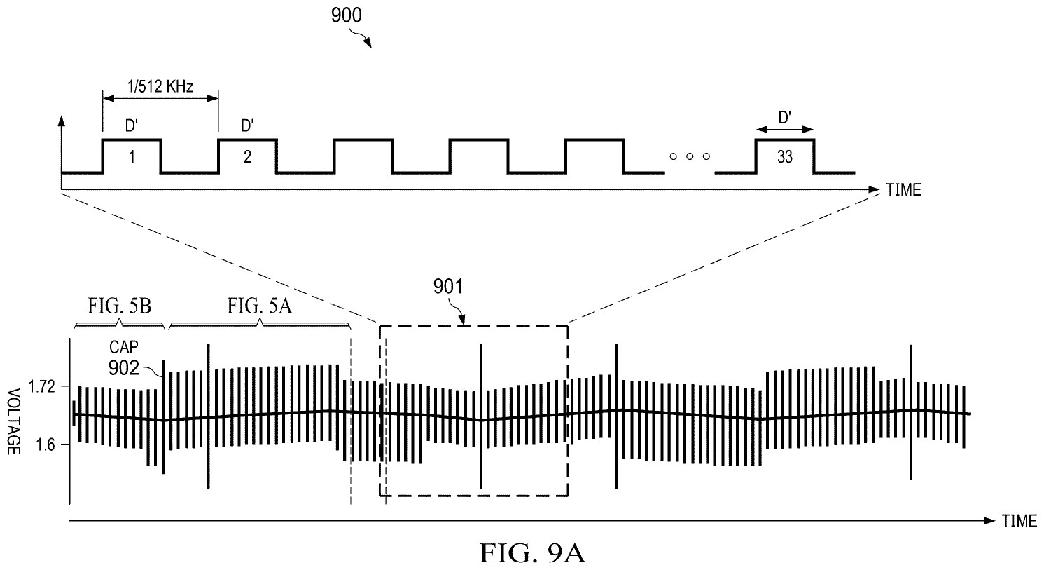

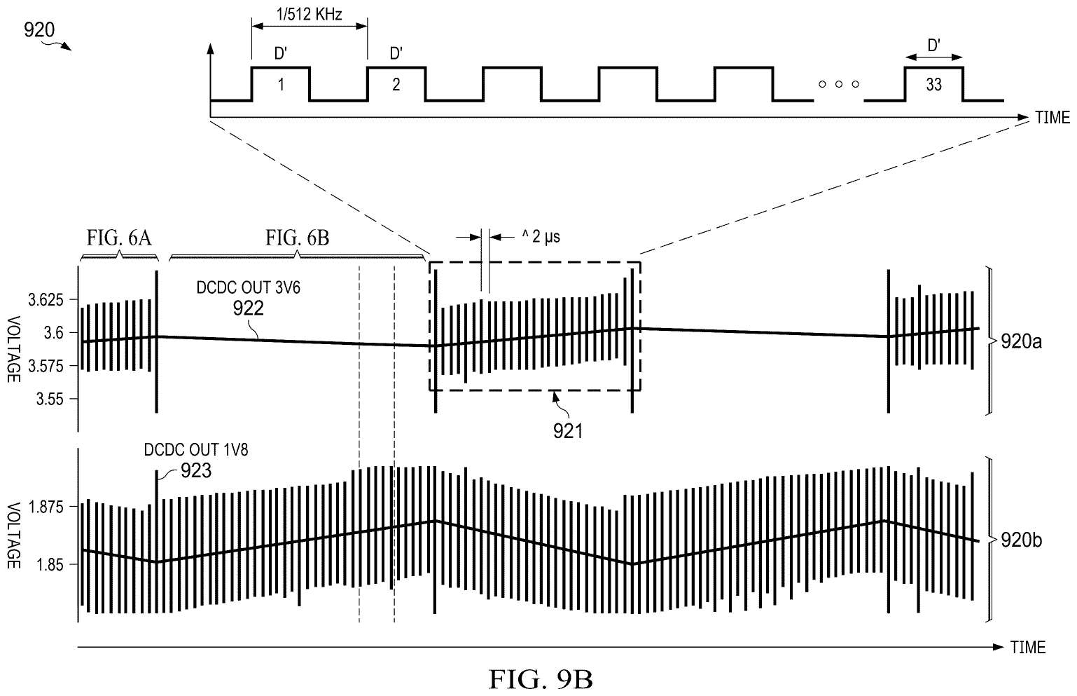

FIG. 9A is a plot 900 illustrating voltage on second capacitor 425 between a secondary power supply terminal and ground during operation modes of FIGS. 5A-B, in accordance with at least one example. FIG. 5A illustrates the operation mode where first switch 422a connects power supply terminal 853 (VDDP_H) to input power terminal 423a of primary side inverter 423, and second switch 422b connects power supply terminal 854 (VDDP_L) to input power terminal 423b of primary side inverter 423. In this operation mode, the voltage on second capacitor 425 charges up. FIG. 5B illustrates the operation mode where first switch 422a couples power supply terminal 854 (VDDP_L) to input power terminal 423a of primary side inverter 423, and second switch 422b couples power supply terminal 855 (PRI_GND) to input power terminal 423b of primary side inverter 423. In this operation mode, the voltage on second capacitor 425 discharges.

An inset 901 shows a zoomed version of switching activity of first multiplexer 422 and its impact on the voltage on power supply terminal 854 (VDDP_L), which is the voltage across second capacitor 425. The steady state voltage on second capacitor 425 is indicated by reference 902, which shows the alternating slow charging and discharging of second capacitor 425 during switching operation of first multiplexer 422. The spikes in plot 900 are caused by switching of DCDC converter during the high pulses on EN signal (see inset 901) derived from digital PWM circuit 735, which operates at lower frequency (e.g., 512 KHz) compared to the switching frequency of quasi-resonant converter 801. In this example, the period of switching of first multiplexer 422 is 1/(512 KHz), where first multiplexer 422 switches during a low pulse and where quasi-resonant converter 801 switches during the high pulse.

FIG. 9B is a set of plots 920 illustrating voltages on secondary side power terminals (858 and 859, or OUTH and OUT_L) during operation modes of FIGS. 6A-B, in accordance with at least one example. The set of plots 920 includes plot 920a, which is the voltage on third capacitor 434, and plot 920b, which is the voltage on fourth capacitor 435.

FIG. 6A illustrates an operation mode where first switch 432a of second multiplexer 432 output power terminal 433c of secondary side rectifier 433 to eighth power supply terminal 858 (OUT_H), and second switch 432b of second multiplexer 432 connects output power terminal 433d of secondary side rectifier 433 to power supply terminal 859 (OUT_L).

An inset 921 shows a zoomed version of switching activity of second multiplexer 432 and its impact on the voltage on eighth power supply terminal 858 (OUT_H), which is the voltage across third capacitor 434. The steady state voltage 922 on third capacitor 434 shows alternating slow charging and discharging of third capacitor 434 during switching operation of second multiplexer 432. The steady state voltage 923 on fourth capacitor 435 shows the alternating slow charging and discharging of fourth capacitor 435 during switching operation of second multiplexer 432.

The ripples in set of plots 920 are caused by the DCDC switching operation during the high value of the pulses that control second multiplexer 432, which operates at lower frequency (e.g., 512 KHz) compared to the switching frequency of quasi-resonant converter 801. In at least one example, the fourth feedback loop operation controls the second multiplexer 432. In this example, the period of switching of second multiplexer 432 is 1/(512 KHz), where second multiplexer 432 switches during a low pulse and where quasi-resonant converter 801 switches during the high pulse.

In the operation mode of FIG. 6A, third capacitor 434 charges while fourth capacitor 435 discharges as indicated by stead state voltages 922 and 923, respectively, for regions of plots 920a and 920b for FIG. 6A. FIG. 6B illustrates an operation mode where first switch 432a of second multiplexer 432 connects output power terminal 433c of secondary side rectifier 433 to power supply terminal 859 (OUT_L), and second switch 432b of second multiplexer 432 connects output power terminal 433b to power supply terminal 860 (SEC_GND). In the operation mode of FIG. 6B, fourth capacitor 435 charges by the current caused by the power transfer from the primary side, while third capacitor 434 is disconnected from secondary side rectifier 433 isolation circuit 108a and does not receive power and may discharge. As shown in plots 920a and 920b, because OUT H is disconnected from secondary side rectifier 433 isolation circuit 108a, OUT_H is not affected by the switching of the primary side inverter and does not have ripples, while plot 920b shows that OUT_L has ripples because it receives power from the primary side due to the switching of the primary side inverter.

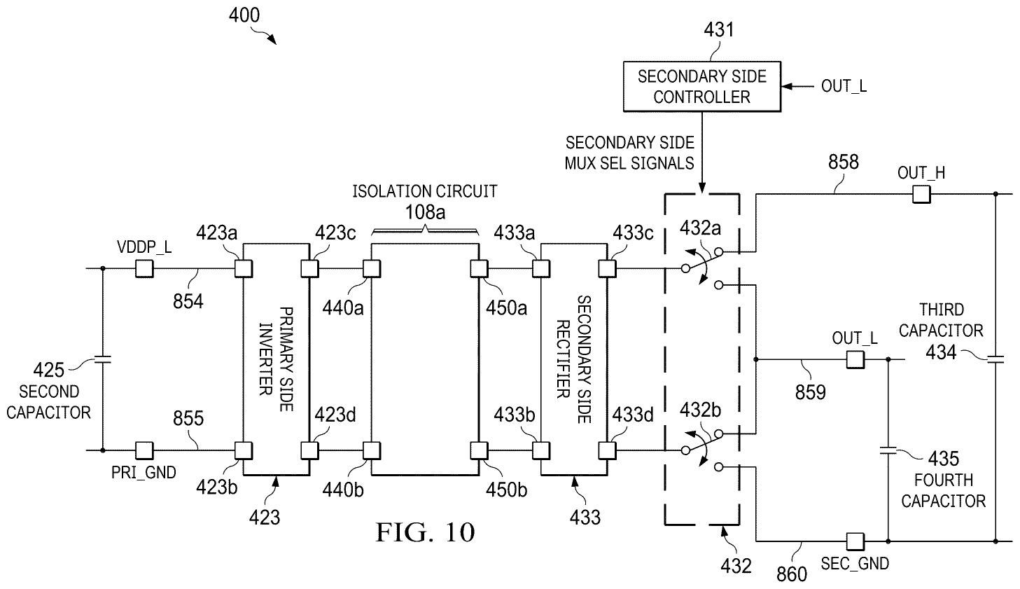

FIG. 10 is a schematic of an example of DC-DC converter 400 with second multiplexer 432 and no primary side multiplexer, in accordance with at least one example. In at least one example, primary side inverter 423 is directly powered by power supply terminal 854 (VDDP_L) and power supply terminal 855 (PRI_GND). This allows primary side inverter 423 to operate with low voltage transistors and smaller inductance for isolation circuit 108a. In at least one example, secondary side rectifier 433 is connected to second multiplexer 432 and operates as discussed with reference to FIGS. 5A, 5B, 6A, 6B, 7, 8, 9A, and 9B.

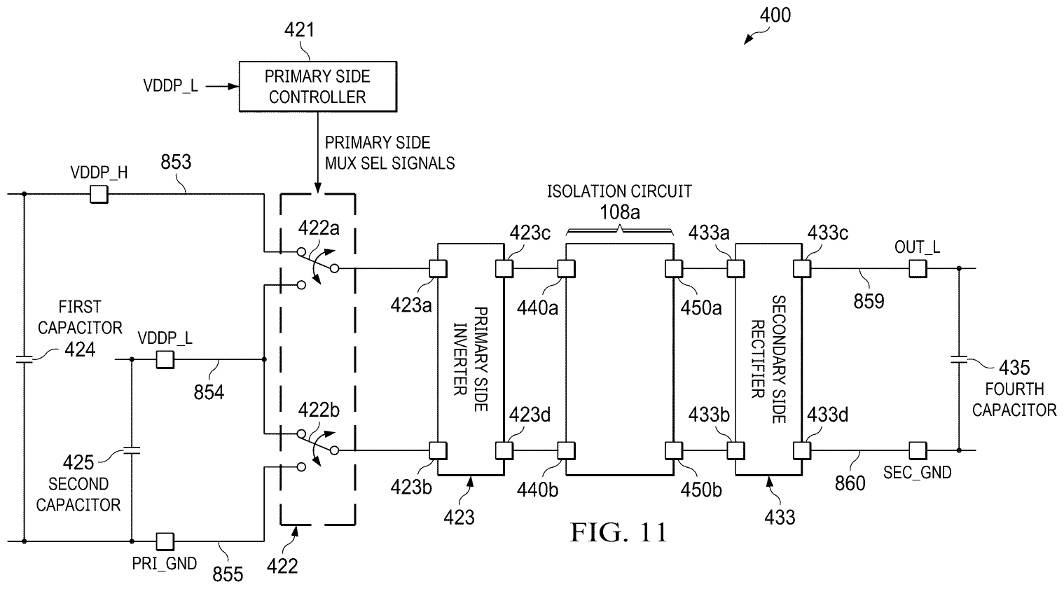

FIG. 11 is a schematic of an example of DC-DC converter 400 with a primary side multiplexer and no secondary side multiplexer, in accordance with at least one example. In at least one example, secondary side rectifier 433 is directly powered by power supply terminal 859 (OUT_L) and power supply terminal 860 (SEC_GND). This allows secondary side rectifier 433 to operate with low voltage transistors and smaller inductance for isolation circuit 108a. In at least one example, primary side inverter 423 is connected to first multiplexer 422 and operates as discussed with reference to FIGS. 5A, 5B, 6A, 6B, 7, 8, 9A, and 9B.

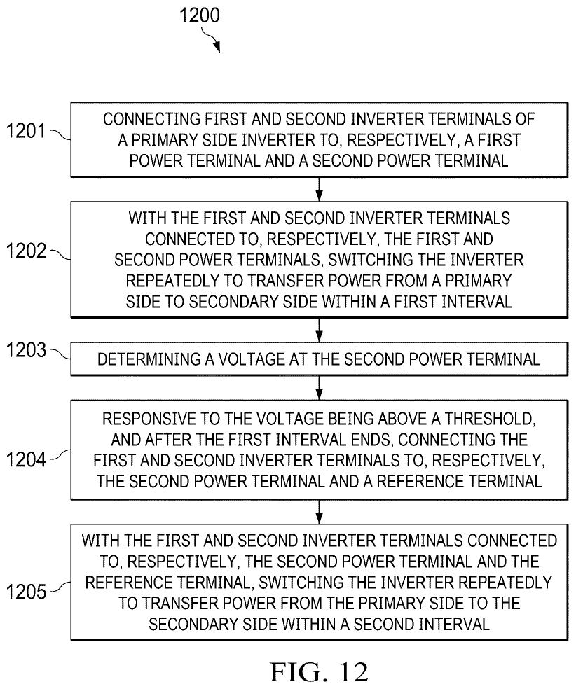

FIG. 12 is a flowchart 1200 of a method of operating a primary side of a DC-DC converter, such as the primary side of DC-DC converter 400. While the blocks of flowchart 1200 are shown in a particular order, the order can be modified. For instance, some blocks can be performed before others, and some may be performed simultaneously. In at least one example, flowchart 1200 is performed by, for example, primary side controller 421, first multiplexer 422, and primary side inverter 423.

At block 1201, in a first primary side operation mode, primary side controller 421 enables first and third switches (MNa4 and Mna2) of first multiplexer 422 and disables second and fourth switches (Mna3 and Mna1) of first multiplexer 422 to connect first and second inverter terminals (input power terminals 423a and 423b) to, respectively, a first power terminal (power supply terminal 853 (VDDP_H)) and a second power terminal (power supply terminal 854 (VDDP_L)), as shown in FIG. 5A. In at least one example, the first switch (Mna4) is coupled between the first power terminal (power supply terminal 853 (VDDP_H)) and the first inverter terminal (input power terminal 423a). In at least one example, the second switch (Mna3) is coupled between the first inverter terminal (input power terminal 423a) and the second power terminal (power supply terminal 854 (VDDP_L)). In at least one example, the third switch (Mna2) is coupled between the second power terminal (power supply terminal 854 (VDDP_L)) and the second inverter terminal (input power terminal 423b). In at least one example, the fourth switch (Mna1) is coupled between the second inverter terminal (input power terminal 423b) and a reference terminal (power supply terminal 855 (PRI_GND)). The voltage at the second power terminal may increase.

At block 1202, while operating first multiplexer 422 in the first primary side operation mode with the first and second inverter terminals connected to, respectively, the first and second power terminals, primary side controller 421 can switch primary side inverter 423 repeatedly to transfer power from a primary side to secondary side within a first interval. The first interval can be defined by a PWM signal provided by digital PWM circuit 735.

At block 1203, primary side controller 421 can determine a voltage at the second power terminal (VDDP_L).

At block 1204, responsive to the voltage being above a first threshold, and after the first interval ends and primary side inverter 423 stop switching, primary side controller 421 can switch to a second primary side operation mode, in which primary side controller 421 enables the second and fourth switches (Mna3 and Mna1) and disables the first and third switches (Mna4 and Mna2) to connect the first and second inverter terminals (input power terminals 423a and 423b) to, respectively, the second power terminal (power supply terminal 854 (VDDP_L)) and the reference terminal (power supply terminal 855 (PRI_GND)), as shown in FIG. 5B.

At block 1205, while operating first multiplexer 422 in the second primary side operation mode with the first and second inverter terminals connected to, respectively, the second power terminal and the reference terminal, primary side controller 421 can switch primary side inverter 423 repeatedly to transfer power from a primary side to secondary side within a second interval. The second interval can be defined by a PWM signal provided by digital PWM circuit 735.

While in the second primary side operation mode, primary side controller 421 can compare the voltage at VDDP_L with a second threshold. If the voltage falls below a second threshold and after the second interval ends and primary side inverter 423 stops switching, primary side controller 421 can switch back to the first primary side operation mode.

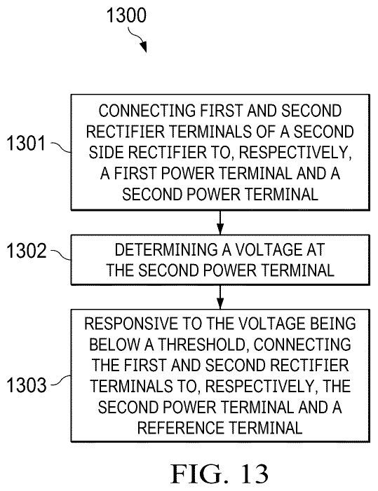

FIG. 13 is a flowchart 1300 of a method of operating a secondary side of a DC-DC converter, such as the secondary side of DC-DC converter 400. While the blocks of flowchart 1200 are shown in a particular order, the order can be modified. For instance, some blocks can be performed before others, and some may be performed simultaneously. In at least one example, flowchart 1300 is performed by, for example, secondary side controller 431, second multiplexer 432, and secondary side rectifier 433.

At block 1301, in a first secondary side operation mode (or a third mode), second multiplexer 432 enables first and third switches (MNb4 and MNb2) and disables second and fourth switches (MNb3 and MNb1) to connect first and second rectifier terminals (output power terminals 433c and 433d) to, respectively, a first power terminal (power supply terminal 858 (OUT_H)) and a second power terminal (power supply terminal 859 (OUT_L)). In at least one example, the first switch (MNb4) is coupled between the first power terminal (eighth power supply terminal 858 (OUT_H)) and the first rectifier terminal (output power terminal 433c). In at least one example, the second switch (MNb3) is coupled between the first rectifier terminal (output power terminal 433d) and the second power terminal (power supply terminal 859 (OUT_L)). In at least one example, the third switch (MNb2) is coupled between the second power terminal (power supply terminal 859 (OUT_L)) and the second rectifier terminal (output power terminal 433d). In at least one example, the fourth switch (MNb1) is coupled between the second rectifier terminal (output power terminal 433d) and a reference terminal (power supply terminal 860 (SEC_GND)), as shown in FIG. 6A. The voltage at the second power terminal may decrease.

At block 1302, while in the first secondary side operation mode, secondary side controller 431 can determine a voltage at the second power terminal (OUT_L).

At block 1303, responsive to the voltage being below a third threshold, secondary side controller 431 can switch to a second secondary side operation mode, in which secondary side controller 431 enables the second and fourth switches (MNb3 and MNb1) and disables the first and third switches (MNb4 and MNb2) to connect the first and second rectifier terminals (output power terminals 433c and 433d) to, respectively, the second power terminal (power supply terminal 859 (OUT_L)) and the reference terminal (power supply terminal 860 (SEC_GND)), as shown in FIG. 6B. Secondary side controller 431 can also switch the second secondary side operation mode based on a signal (e.g., from rectifier activity detection circuit 870) indicating that the primary side inverter is not switching and no power is transferred from the primary side to the secondary side.

While in the second secondary side operation mode, secondary side controller 431 can compare the voltage at OUT_L with a fourth threshold, and if the voltage exceeds the fourth threshold, secondary side controller 431 can switch back to the first secondary side operation mode. The switching back to the first secondary side operation mode can also occur based on the signal from rectifier activity detection circuit 870 indicating that the primary side inverter is not switching and no power is transferred from the primary side to the secondary side.

The following are additional examples provided in view of the above-described implementations. Here, one or more features of example, in isolation or in combination, can be combined with one or more features of one or more other examples to form further examples also falling within the scope of the disclosure. As such, one implementation can be combined with one or more other implementations without changing the scope of disclosure.

Example 1 is an apparatus comprising: a first switch coupled between a first power terminal and a first inverter terminal, the first switch having a first switch control input; a second switch coupled between the first inverter terminal and a second power terminal, the second switch having a second switch control input; a third switch coupled between the second power terminal and a second inverter terminal, the third switch having a third switch control input; a fourth switch coupled between the second inverter terminal and a reference terminal, the fourth switch having a fourth switch control input; and an inverter circuit coupled between first and second inverter terminals, the inverter circuit having outputs coupled to primary side terminals.

Example 2 is an apparatus according to any example herein, in particular example 1, further comprising a control circuit having outputs coupled to the first, second, third, and fourth switch control inputs; wherein the control circuit is configured to: in a first mode, enable the first and third switches and disable the second and fourth switches to connect the first and second inverter terminals to, respectively, the first power terminal and the second power terminal; and in a second mode, enable the second and fourth switches and disable the first and third switches to connect the first and second inverter terminals to, respectively, the second power terminal and the reference terminal.

Example 3 is an apparatus according to any example herein, in particular example 2, wherein the control circuit is configured to switch between the first and second modes based on comparing a voltage at the second power terminal with a reference voltage.

Example 4 is an apparatus according to any example herein, in particular example 2, wherein the control circuit is configured to set relative durations of the first and second modes based on comparing a voltage at the second power terminal with a reference voltage.

Example 5 is an apparatus according to any example herein, in particular example 1, wherein the first, second, third, fourth switches, the inverter circuit, and the control circuit are part of a semiconductor die.

Example 6 is an apparatus according to any example herein, in particular example 5, further comprising an isolation circuit including at least one of: a transformer, a pair of capacitors, or a pair of piezoelectric devices.

Example 7 is an apparatus according to any example herein, in particular example 6, wherein the isolation circuit and the semiconductor die are part of a packaged integrated circuit having a package substrate, wherein the isolation circuit is part of or formed on the package substrate, and the semiconductor die is mounted on the package substrate.

Example 8 is an apparatus according to any example herein, in particular example 7, further comprising a first capacitor coupled to the first power terminal and a second capacitor coupled to the second power terminal.

Example 9 is an apparatus according to any example herein, in particular example 8, wherein the first and second capacitors are external to the packaged integrated circuit.

Example 10 is an apparatus according to any example herein, in particular example 1, wherein the reference terminal is a first reference terminal, the control circuit is a first control circuit, and the apparatus further comprises: a fifth switch coupled between a third power terminal and a first rectifier terminal, the fifth switch having a fifth switch control input; a sixth switch coupled between the first rectifier terminal and a fourth power terminal, the sixth switch having a sixth switch control input; a seventh switch coupled between the fourth power terminal and a second rectifier terminal, the seventh switch having a seventh switch control input; an eighth switch coupled between the second rectifier terminal and a second reference terminal, the eighth switch having an eighth switch control input; a rectifier circuit coupled between the first and second rectifier terminals, the rectifier circuit having inputs coupled to secondary side winding; and a second control circuit having outputs coupled to the fifth, sixth, seventh, and eighth switch control inputs.

Example 11 is an apparatus according to any example herein, in particular example 10, wherein: the first, second, third, fourth switches, the inverter circuit, and the control circuit are part of a first semiconductor die of a packaged integrated circuit; and the fifth, sixth, seventh, and eighth switches, the second rectifier circuit, and the second control circuit are part of a second semiconductor die of the packaged integrated circuit.

Example 12 is an apparatus according to any example herein, in particular example 11, further comprising a third capacitor coupled to the third power terminal and a fourth capacitor coupled to the fourth power terminal.

Example 13 is an apparatus according to any example herein, in particular example 12, wherein the third and fourth capacitors are external to the packaged integrated circuit.

Example 14 is an apparatus according to any example herein, in particular example 10, wherein the second control circuit is configured to: in a third mode, enable the fifth and seventh switches and disable the sixth and eighth switches to connect the first and second rectifier terminals to, respectively, the third power terminal and the fourth power terminal; and in a fourth mode, enable the sixth and eighth switches and disable the fifth and seventh switches to connect the first and second rectifier terminals to, respectively, the fourth power terminal and the second reference terminal.

Example 15 is an apparatus according to any example herein, in particular example 14, wherein the second control circuit is configured to switch between the third and fourth modes based on comparing a voltage at the fourth power terminal with a reference voltage.

Example 16 is an apparatus according to any example herein, in particular example 15, wherein the second control circuit is configured to set relative durations of the third and fourth modes based on comparing a voltage at the second power terminal with a reference voltage.

Example 17 is an apparatus according to any example herein, in particular example 10, further comprising a rectifier activity detection circuit having inputs coupled to the rectifier circuit and an output coupled to the second control circuit.

Example 18 is an apparatus according to any example herein, in particular example 7, wherein the inverter circuit has switching inputs, and the apparatus further comprises a switching signal generator having an output coupled to the switching inputs of the inverter circuit.

Example 19 is an apparatus according to any example herein, in particular example 18, further comprising: a pulse width modulation (PWM) circuit having a PWM output; and a logic circuit having a first input, a second input, and an output, the first input of the logic circuit coupled to the PWM output, the second input of the logic circuit coupled to the output of the switching signal generator, and the switching inputs of the inverter circuit coupled to the output of the logic circuit.

Example 20 is an apparatus according to any example herein, in particular example 19, wherein the isolation circuit is a first isolation circuit, and the apparatus further comprises: a second isolation circuit having second primary side terminals and second secondary side terminals, the second isolation circuit being part of or formed on the package substrate; a transmit circuit having outputs coupled to the second primary side terminal; an analog-to-digital converter (ADC) circuit having an input and an output, the input of the ADC circuit coupled to the third power terminal, and the output of the ADC circuit coupled to the input of the transmit circuit; and a receive circuit having inputs coupled to the second secondary side terminals, an output of the receive circuit coupled to an input of the PWM circuit.

Example 21 is an apparatus according to any example herein, in particular example 1, further comprising a startup circuit coupled between the first and second power terminals and configured to set an initial voltage of the second power terminal.

Example 22 is an apparatus according to any example herein, in particular example 21, wherein the startup circuit is a first startup circuit, wherein the apparatus further comprising a second startup circuit coupled between the third and fourth power terminals and configured to set an initial voltage of the fourth power terminal.

Example 23 is an apparatus comprising: a first switch coupled between a first power terminal and a first rectifier terminal, the first switch having a first switch control input; a second switch coupled between the first rectifier terminal and a second power terminal, the second switch having a second switch control input; a third switch coupled between the second power terminal and a second rectifier terminal, the third switch having a third switch control input; a fourth switch coupled between the second rectifier terminal and a reference terminal, the fourth switch having a fourth switch control input; and a rectifier circuit coupled between the first and second rectifier terminals, the rectifier circuit having inputs coupled to secondary side terminals.

Example 24 is an apparatus according to any example herein, in particular example 23 further comprising a control circuit having outputs coupled to the first, second, third, and fourth switch control inputs, wherein the control circuit is configured to: in a first mode, enable the first and third switches and disable the second and fourth switches to connect the first and second rectifier terminals to, respectively, the first power terminal and the second power terminal; and in a second mode, enable the second and fourth switches and disable the first and third switches to connect the first and second rectifier terminals to, respectively, the second power terminal and the reference terminal.

Example 25 is an apparatus according to any example herein, in particular example 23, wherein the reference terminal is a first reference terminal, wherein the apparatus further comprises: a fifth switch coupled between a third power terminal and a first inverter terminal, the fifth switch having a fifth switch control input; a sixth switch coupled between the first inverter terminal and a fourth power terminal, the sixth switch having a sixth switch control input; a seventh switch coupled between the fourth power terminal and a second inverter terminal, the seventh switch having a seventh switch control input; an eighth switch coupled between the second inverter terminal and a second reference terminal, the eighth switch having an eighth switch control input; and an inverter circuit coupled between first and second inverter terminals, the inverter circuit having outputs coupled to primary side terminals.

Example 26 is an apparatus according to any example herein, in particular example 25, further comprising a second control circuit having outputs coupled to the fifth, sixth, seventh, and eighth switch control inputs; wherein the second control circuit is configured to: in a third mode, enable the fifth and seventh switches and disable the sixth and eighth switches to connect the first and second inverter terminals to, respectively, the third power terminal and the fourth power terminal; and in a fourth mode, enable the sixth and eighth switches and disable the fifth and seventh switches to connect the first and second inverter terminals to, respectively, the fourth power terminal and the second reference terminal.

Example 27 is an apparatus comprising: a first multiplexer circuit having a first selection input and a second selection input, the first multiplexer circuit configured to connect between a first power terminal and a first inverter terminal or between a second power terminal and the first inverter terminal responsive to a state of the first selection input, wherein the first multiplexer circuit is configured to connect between the second power terminal and a second inverter terminal or between a first reference terminal and the second inverter terminal responsive to a state of the second selection input; an inverter circuit coupled between the first and second inverter terminals; a first control circuit having outputs coupled to the first and second selection inputs; a rectifier circuit coupled between first and second rectifier terminals; a second multiplexer circuit having a third selection input and fourth selection input, the third multiplexer circuit configured to connect between a third power terminal and the first rectifier terminal or between a fourth power terminal and the first rectifier terminal responsive to a state of the third selection input, wherein the second multiplexer circuit is configured to connect between the fourth power terminal and the second rectifier terminal or between a second reference terminal and the second rectifier terminal responsive to a state of the fourth selection input; a second control circuit having outputs coupled to the third and fourth selection inputs; and an isolation circuit having primary side winding and secondary side winding, the primary side winding coupled to outputs of the inverter circuit, and the secondary side winding coupled to inputs of the rectifier circuit.

Example 28 is an apparatus according to any example herein, in particular example 27, wherein the first control circuit is configured to alternate between first and second modes, wherein: in the first mode, the first control circuit is configured to enable first and third switches and disable second and fourth switches to connect the first and second rectifier terminals to, respectively, the first power terminal and the second power terminal, wherein the first multiplexer circuit includes the first, second, third, and fourth switches; and in a second mode, the first control circuit is configured to enable the second and fourth switches and disable the first and third switches to connect the first and second rectifier terminals to, respectively, the second power terminal and the reference terminal.

Example 29 is an apparatus according to any example herein, in particular example 28, wherein the first control circuit is configured to set relative durations of the first and second modes based on comparing a voltage at the second power terminal with a first reference voltage on the first reference terminal.

Example 30 is an apparatus according to any example herein, in particular example 27, further comprising a first capacitor coupled to the first power terminal and a second capacitor coupled to the second power terminal.

Example 31 is an apparatus according to any example herein, in particular example 30, wherein the first and second capacitors are external to a packaged integrated circuit.

Example 32 is an apparatus according to any example herein, in particular example 27, further comprising a third capacitor coupled to the third power terminal and a fourth capacitor coupled to the fourth power terminal.

Example 33 is an apparatus according to any example herein, in particular example 32, wherein the third and fourth capacitors are external to a packaged integrated circuit.

Example 34 is a method comprising: in a first mode, connecting first and second inverter terminals of a primary side inverter to, respectively, a first power terminal and a second power terminal; while in the first mode, switching the primary side inverter to transfer power from a primary side to a secondary side within a first interval; determining a voltage at the second power terminal; responsive to the voltage being above a threshold, and after the first interval ends, switching from the first mode to a second mode, in which in the second mode, connecting the first and second inverter terminals to, respectively, the second power terminal and a reference terminal; and while in the second mode, switching the primary side inverter to transfer power from a primary side to a secondary side within a second interval.

Example 35 is a method according to any example herein, in particular example 34, wherein the threshold is a first threshold, and the method further comprises: determining the voltage at the second power terminal; and responsive to the voltage being below a second threshold, and after the second interval ends, switching from the second mode back to the first mode.

Example 36 is a method comprising: in a first mode, connecting first and second rectifier terminals of a second side rectifier to, respectively, a first power terminal and a second power terminal; while in the first mode, determining a voltage at the second power terminal; and responsive to the voltage being below a threshold, switching from the first mode to a second mode, in which in the second mode, connecting the first and second rectifier terminals to, respectively, the second power terminal and a reference terminal.

Example 37 is a method according to any example herein, in particular example 36, wherein the threshold is a first threshold, and the method further comprises: determining the voltage at the second power terminal; and responsive to the voltage being below a second threshold, switching from the second mode back to the first mode.

Example 38 is a method comprising: in a first mode, enabling first and third switches and disabling second and fourth switches to connect first and second inverter terminals to, respectively, a first power terminal and a second power terminal; in a second mode, enabling the second and fourth switches and disabling the first and third switches to connect the first and second inverter terminals to, respectively, the second power terminal and the reference terminal; and alternating between the first and second modes.

Example 39 is a method according to any example herein, in particular example 38, wherein: the first switch is coupled between the first power terminal and the first inverter terminal, the first switch having a first switch control input; the second switch is coupled between the first inverter terminal and the second power terminal, the second switch having a second switch control input; the third switch is coupled between the second power terminal and a second inverter terminal, the third switch having a third switch control input; the fourth switch is coupled between the second inverter terminal and a reference terminal, the fourth switch having a fourth switch control input; and the first and second inverter terminals are coupled to an inverter circuit, wherein the inverter circuit has outputs coupled to primary side terminals.

Example 40 is a method according to any example herein, in particular example 38, further comprising setting relative durations of the first and second modes based on comparing a voltage at the second power terminal with a reference voltage.

Example 41 is a method according to any example herein, in particular example 39, wherein the primary side terminals are coupled to a primary side winding of a transformer, the transformer further having a second side winding, wherein secondary side winding is coupled to secondary side windings, which is coupled to inputs of a rectifier circuit, wherein the rectifier circuit is coupled between first and second rectifier terminals, wherein: a fifth switch is coupled between a third power terminal and the first rectifier terminal, the fifth switch having a fifth switch control input; a sixth switch is coupled between the first rectifier terminal and a fourth power terminal, the sixth switch having a sixth switch control input; a seventh switch is coupled between the fourth power terminal and the second rectifier terminal, the seventh switch having a seventh switch control input; and an eighth switch is coupled between the second rectifier terminal and a second reference terminal, the eighth switch having an eighth switch control input.

Example 42 is a packaged integrated circuit comprising: a first semiconductor die; a second semiconductor die; and a transformer coupled to the first semiconductor die and the second semiconductor die, wherein the first semiconductor die comprises: a full bridge inverter coupled to a first power supply terminal and a second power supply terminal, wherein the first power supply terminal has a voltage level lower than a voltage level of the second power supply terminal; and a multiplexer to selectively couple a third power supply terminal to the first power supply terminal and a fourth power supply terminal to the second power supply terminal in a first operation mode, and couple the fourth power supply terminal to first power supply terminal and a fifth power supply terminal to the second power supply terminal in a second operation mode.

Example 43 is a packaged integrated circuit according to packaged integrated circuit example herein, in particular example 42, wherein the first semiconductor die includes a first voltage regulator to regulate a voltage on the fourth power supply terminal based on a first reference voltage.

Example 44 is a packaged integrated circuit according to packaged integrated circuit example herein, in particular example 43, wherein the first voltage regulator has an operating frequency lower than an operating frequency of the full bridge inverter.

Example 45 is a packaged integrated circuit according to packaged integrated circuit example herein, in particular example 43, wherein the third power supply terminal is coupled to the fifth power supply terminal via a first capacitor, and wherein the fourth power supply terminal is coupled to the fifth power supply terminal via a second capacitor.

Example 46 is a packaged integrated circuit according to packaged integrated circuit example herein, in particular example 42, wherein the first semiconductor die includes a source follower coupled between the third power supply terminal and the fourth power supply terminal to precharge a voltage on the fourth power supply terminal.

Example 47 is a packaged integrated circuit according to packaged integrated circuit example herein, in particular example 43, wherein the multiplexer is a first multiplexer, wherein the second semiconductor die includes: a full bridge rectifier coupled to a sixth power supply terminal and a seventh power supply terminal, wherein the sixth power supply terminal has a voltage level lower than a voltage level of the seventh power supply terminal; and a second multiplexer to selectively couple an eighth power supply terminal to the third power supply terminal and a ninth power supply terminal to the seventh power supply terminal in the first operation mode, and couple the ninth power supply terminal to first power supply terminal and a tenth power supply terminal to the seventh power supply terminal in the second operation mode.

Example 48 is a packaged integrated circuit according to packaged integrated circuit example herein, in particular example 47, wherein the second semiconductor die includes a second voltage regulator to regulate a voltage on the ninth power supply terminal based on a second reference voltage.

Example 48 is a packaged integrated circuit according to packaged integrated circuit example herein, in particular example 47, wherein the second voltage regulator has an operating frequency lower than an operating frequency of the full bridge inverter or the full bridge rectifier.

Example 50 is a packaged integrated circuit according to packaged integrated circuit example herein, in particular example 47, wherein the eighth power supply terminal is coupled to the tenth power supply terminal via a third capacitor, and wherein the ninth power supply terminal is coupled to the tenth power supply terminal via a fourth capacitor.

Example 51 is a packaged integrated circuit according to packaged integrated circuit example herein, in particular example 50, wherein charge is transferred from the fourth capacitor to the third capacitor based on coupling of the sixth power supply terminal to the eighth power supply terminal and coupling of the seventh power supply terminal to the ninth power supply terminal.

Example 52 is a packaged integrated circuit according to packaged integrated circuit example herein, in particular example 47, wherein the transformer is a first transformer, wherein the packaged integrated circuit further includes: a third semiconductor die; a fourth semiconductor die; and a second transformer coupled to the third semiconductor die and the fourth semiconductor die, wherein the third semiconductor die includes: a receiver coupled to the second transformer; a digital control circuit coupled to the receiver; and a digital pulse width modulation circuit coupled to the digital control circuit, wherein an operating frequency of the first voltage regulator is controlled by an output of the digital pulse width modulation circuit.

Example 53 is a packaged integrated circuit according to packaged integrated circuit example herein, in particular example 52, wherein the fourth semiconductor die includes: a transmitter coupled to the second transformer; and an analog-to-digital converter circuit coupled to the transmitter, wherein the analog-to-digital converter circuit has an input coupled to the eighth power supply terminal to sample a voltage of the eighth power supply terminal and convert it to a digital representation for transmission by the transmitter to the receiver via the second transformer.

Example 54 is a packaged integrated circuit according to packaged integrated circuit example herein, in particular example 52, wherein the first transformer and the second transformer are in an isolation barrier.

Example 55 is a packaged integrated circuit according to packaged integrated circuit example herein, in particular example 47, wherein the full bridge inverter and the full bridge rectifier are in an off state in the first operation mode and the second operation mode, wherein the first multiplexer and the second multiplexer are active in the first operation mode and the second operation mode, and inactive when the full bridge inverter and the full bridge rectifier are in an on state.

Example 56 is a packaged integrated circuit according to packaged integrated circuit example herein, in particular example 47, wherein switching states of the full bridge inverter and the full bridge rectifier are based on an active or inactive state of the first multiplexer and the second multiplexer.

Example 57 is a packaged integrated circuit comprising: a first semiconductor die; a second semiconductor die; and a transformer coupled to the first semiconductor die and the second semiconductor die, wherein the first semiconductor die comprises: a full bridge inverter to operate with a first set of power supply terminals in a first operation mode, and with a second set of power supply terminals in a second operation mode; and a multiplexer to selectively couple a third set of power supply terminals to the first set of power supply terminals in the first operation mode, and a fourth set of power supply terminals to the second set of power supply terminals in the second operation mode.

Example 58 is a packaged integrated circuit according to packaged integrated circuit example herein, in particular example 57, wherein the second semiconductor die includes:
a full bridge rectifier coupled to the transformer to operate with a fifth set of power supply terminals in the first operation mode, and with a sixth set of power supply terminals in the second operation mode; and a second multiplexer to selectively couple the fifth set of power supply terminals to a seventh set of power supply terminals in the first operation mode, and the sixth set of power supply terminals to an eighth set of power supply terminals in the second operation mode.

Example 59 is a packaged integrated circuit according to packaged integrated circuit example herein, in particular example 58, wherein the transformer is a first transformer, wherein the packaged integrated circuit further includes: a third semiconductor die; a fourth semiconductor die; and a second transformer coupled to the third semiconductor die and the fourth semiconductor die, wherein the third semiconductor die includes: a receiver coupled to the second transformer; a digital control circuit coupled to the receiver; and a digital pulse width modulation circuit coupled to the digital control circuit, wherein a switching frequency of the full bridge inverter is controlled by an output of the digital pulse width modulation circuit.

Example 60 is a packaged integrated circuit according to packaged integrated circuit example herein, in particular example 59, wherein the fourth semiconductor die includes: a transmitter coupled to the second transformer; and an analog-to-digital converter circuit coupled to the transmitter, wherein the analog-to-digital converter circuit has an input coupled to a power supply terminal of the seventh set of power supply terminals to sample a voltage of the power supply terminal and convert it to a digital representation for transmission by the transmitter to the receiver via the second transformer.

Example 61 is a method comprising: enabling, in first operation mode, a full bridge inverter coupled to a first power supply terminal and a second power supply terminal, wherein the first power supply terminal has a voltage level lower than a voltage level of the second power supply terminal; inductively coupling an output of the full bridge inverter to a full bridge rectifier via a transformer in an isolation barrier; selectively coupling the first power supply terminal to a third power supply terminal and the second power supply terminal to a fourth power supply terminal in a second operation mode separate from the first operation mode; selectively coupling the first power supply terminal to the fourth power supply terminal and the second power supply terminal to a fifth power supply terminal in a third operation mode separate from the first operation mode and the second operation mode; and disabling the full bridge inverter during the third operation mode and the second operation mode.

Example 62 is a method according to packaged integrated circuit example herein, in particular example 61 further including: regulating voltage on the fourth power supply terminal.

Example 63 is a method according to packaged integrated circuit example herein, in particular example 61 further including: receiving, by the full bridge rectifier, the output via the transformer, the full bridge rectifier coupled to a sixth power supply terminal and a seventh power supply terminal, wherein the sixth power supply terminal has a voltage level lower than a voltage level of the seventh power supply terminal; selectively coupling an eighth power supply terminal to the third power supply terminal and a ninth power supply terminal to the seventh power supply terminal in the first operation mode; and selectively coupling the ninth power supply terminal to first power supply terminal and a tenth power supply terminal to the seventh power supply terminal in the second operation mode.

Besides what is described herein, various modifications can be made to disclose implementations and implementations thereof without departing from their scope. Therefore, illustrations of implementations herein should be construed as examples, and not restrictive to scope of present disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In the description and in the claims, the terms “including” and “having” and variants thereof are intended to be inclusive in a manner similar to the term “comprising” unless otherwise noted. In addition, the terms “couple,” “coupled,” or “couples” means an indirect or direct electrical or mechanical connection.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics, or semiconductor component.

A circuit or device that is described herein as including certain components may instead be adapted to be coupled to those components to form the described circuit or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuit. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN), or a gallium arsenide substrate (GaAs).

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately,” or “substantially” preceding a parameter means being within +/−10 percent of that parameter or, if the parameter is zero, a reasonable range of values around zero.

What is claimed is:

1. An apparatus comprising:
a first switch coupled between a first power terminal and a first inverter terminal, the first switch having a first switch control input;
a second switch coupled between the first inverter terminal and a second power terminal, the second switch having a second switch control input;
a third switch coupled between the second power terminal and a second inverter terminal, the third switch having a third switch control input;
a fourth switch coupled between the second inverter terminal and a reference terminal, the fourth switch having a fourth switch control input; and
an inverter circuit coupled between first and second inverter terminals, the inverter circuit having outputs coupled to primary side terminals.

2. The apparatus of claim 1, further comprising a control circuit having outputs coupled to the first, second, third, and fourth switch control inputs;
wherein the control circuit is configured to:
in a first mode, enable the first and third switches and disable the second and fourth switches to connect the first and second inverter terminals to, respectively, the first power terminal and the second power terminal; and
in a second mode, enable the second and fourth switches and disable the first and third switches to connect the first and second inverter terminals to, respectively, the second power terminal and the reference terminal.

3. The apparatus of claim 2, wherein the control circuit is configured to switch between the first and second modes based on comparing a voltage at the second power terminal with a reference voltage.

4. The apparatus of claim 2, wherein the control circuit is configured to set relative durations of the first and second modes based on comparing a voltage at the second power terminal with a reference voltage.

5. The apparatus of claim 1, wherein the first, second, third, fourth switches, the inverter circuit, and the control circuit are part of a semiconductor die.

6. The apparatus of claim 5, further comprising an isolation circuit including at least one of: a transformer, a pair of capacitors, or a pair of piezoelectric devices.

7. The apparatus of claim 6, wherein the isolation circuit and the semiconductor die are part of a packaged integrated circuit having a package substrate, wherein the isolation circuit is part of or formed on the package substrate, and the semiconductor die is mounted on the package substrate.

8. The apparatus of claim 7, further comprising a first capacitor coupled to the first power terminal and a second capacitor coupled to the second power terminal.

9. The apparatus of claim 8, wherein the first and second capacitors are external to the packaged integrated circuit.

10. The apparatus of claim 1, wherein the reference terminal is a first reference terminal, the control circuit is a first control circuit, and the apparatus further comprises:
a fifth switch coupled between a third power terminal and a first rectifier terminal, the fifth switch having a fifth switch control input;
a sixth switch coupled between the first rectifier terminal and a fourth power terminal, the sixth switch having a sixth switch control input;
a seventh switch coupled between the fourth power terminal and a second rectifier terminal, the seventh switch having a seventh switch control input;
an eighth switch coupled between the second rectifier terminal and a second reference terminal, the eighth switch having an eighth switch control input;
a rectifier circuit coupled between the first and second rectifier terminals, the rectifier circuit having inputs coupled to secondary side winding; and
a second control circuit having outputs coupled to the fifth, sixth, seventh, and eighth switch control inputs.

11. The apparatus of claim 10, wherein:
the first, second, third, fourth switches, the inverter circuit, and the control circuit are part of a first semiconductor die of a packaged integrated circuit; and
the fifth, sixth, seventh, and eighth switches, the second rectifier circuit, and the second control circuit are part of a second semiconductor die of the packaged integrated circuit.

12. The apparatus of claim 11, further comprising a third capacitor coupled to the third power terminal and a fourth capacitor coupled to the fourth power terminal.

13. The apparatus of claim 12, wherein the third and fourth capacitors are external to the packaged integrated circuit.

14. The apparatus of claim 10, wherein the second control circuit is configured to:
in a third mode, enable the fifth and seventh switches and disable the sixth and eighth switches to connect the first and second rectifier terminals to, respectively, the third power terminal and the fourth power terminal; and
in a fourth mode, enable the sixth and eighth switches and disable the fifth and seventh switches to connect the first and second rectifier terminals to, respectively, the fourth power terminal and the second reference terminal.

15. The apparatus of claim 14, wherein the second control circuit is configured to switch between the third and fourth modes based on comparing a voltage at the fourth power terminal with a reference voltage.

16. The apparatus of claim 15, wherein the second control circuit is configured to set relative durations of the third and fourth modes based on comparing a voltage at the second power terminal with a reference voltage.

17. The apparatus of claim 10, further comprising a rectifier activity detection circuit having inputs coupled to the rectifier circuit and an output coupled to the second control circuit.

18. The apparatus of claim 7, wherein the inverter circuit has switching inputs, and the apparatus further comprises a switching signal generator having an output coupled to the switching inputs of the inverter circuit.

19. The apparatus of claim 18, further comprising:
a pulse width modulation (PWM) circuit having a PWM output; and
a logic circuit having a first input, a second input, and an output, the first input of the logic circuit coupled to the PWM output, the second input of the logic circuit coupled to the output of the switching signal generator, and the switching inputs of the inverter circuit coupled to the output of the logic circuit.

20. The apparatus of claim 19, wherein the isolation circuit is a first isolation circuit, and the apparatus further comprises:
a second isolation circuit having second primary side terminals and second secondary side terminals, the second isolation circuit being part of or formed on the package substrate;
a transmit circuit having outputs coupled to the second primary side terminal;
an analog-to-digital converter (ADC) circuit having an input and an output, the input of the ADC circuit coupled to the third power terminal, and the output of the ADC circuit coupled to the input of the transmit circuit; and
a receive circuit having inputs coupled to the second secondary side terminals, an output of the receive circuit coupled to an input of the PWM circuit.

21. The apparatus of claim 1, further comprising a startup circuit coupled between the first and second power terminals and configured to set an initial voltage of the second power terminal.

22. The apparatus of claim 21, wherein the startup circuit is a first startup circuit, wherein the apparatus further comprising a second startup circuit coupled between the third and fourth power terminals and configured to set an initial voltage of the fourth power terminal.

23. An apparatus comprising:
a first switch coupled between a first power terminal and a first rectifier terminal, the first switch having a first switch control input;
a second switch coupled between the first rectifier terminal and a second power terminal, the second switch having a second switch control input;
a third switch coupled between the second power terminal and a second rectifier terminal, the third switch having a third switch control input;
a fourth switch coupled between the second rectifier terminal and a reference terminal, the fourth switch having a fourth switch control input; and
a rectifier circuit coupled between the first and second rectifier terminals, the rectifier circuit having inputs coupled to secondary side terminals.

24. The apparatus of claim 23 further comprising a control circuit having outputs coupled to the first, second, third, and fourth switch control inputs, wherein the control circuit is configured to:
in a first mode, enable the first and third switches and disable the second and fourth switches to connect the first and second rectifier terminals to, respectively, the first power terminal and the second power terminal; and
in a second mode, enable the second and fourth switches and disable the first and third switches to connect the first and second rectifier terminals to, respectively, the second power terminal and the reference terminal.

25. The apparatus of claim 23, wherein the reference terminal is a first reference terminal, wherein the apparatus further comprises:
a fifth switch coupled between a third power terminal and a first inverter terminal, the fifth switch having a fifth switch control input;
a sixth switch coupled between the first inverter terminal and a fourth power terminal, the sixth switch having a sixth switch control input;
a seventh switch coupled between the fourth power terminal and a second inverter terminal, the seventh switch having a seventh switch control input;
an eighth switch coupled between the second inverter terminal and a second reference terminal, the eighth switch having an eighth switch control input; and
an inverter circuit coupled between first and second inverter terminals, the inverter circuit having outputs coupled to primary side terminals.

26. The apparatus of claim 25, further comprising a second control circuit having outputs coupled to the fifth, sixth, seventh, and eighth switch control inputs;
wherein the second control circuit is configured to:
in a third mode, enable the fifth and seventh switches and disable the sixth and eighth switches to connect the first and second inverter terminals to, respectively, the third power terminal and the fourth power terminal; and
in a fourth mode, enable the sixth and eighth switches and disable the fifth and seventh switches to connect the first and second inverter terminals to, respectively, the fourth power terminal and the second reference terminal.

27. An apparatus comprising:
a first multiplexer circuit having a first selection input and a second selection input, the first multiplexer circuit configured to connect between a first power terminal and a first inverter terminal or between a second power terminal and the first inverter terminal responsive to a state of the first selection input, wherein the first multiplexer circuit is configured to connect between the second power terminal and a second inverter terminal or between a first reference terminal and the second inverter terminal responsive to a state of the second selection input;
an inverter circuit coupled between the first and second inverter terminals;
a first control circuit having outputs coupled to the first and second selection inputs;
a rectifier circuit coupled between first and second rectifier terminals;
a second multiplexer circuit having a third selection input and fourth selection input, the third multiplexer circuit configured to connect between a third power terminal and the first rectifier terminal or between a fourth power terminal and the first rectifier terminal responsive to a state of the third selection input, wherein the second multiplexer circuit is configured to connect between the fourth power terminal and the second rectifier terminal or between a second reference terminal and the second rectifier terminal responsive to a state of the fourth selection input;
a second control circuit having outputs coupled to the third and fourth selection inputs; and
an isolation circuit having primary side winding and secondary side winding, the primary side winding coupled to outputs of the inverter circuit, and the secondary side winding coupled to inputs of the rectifier circuit.

28. The apparatus of claim 27, wherein the first control circuit is configured to alternate between first and second modes, wherein:
in the first mode, the first control circuit is configured to enable first and third switches and disable second and fourth switches to connect the first and second rectifier terminals to, respectively, the first power terminal and the second power terminal, wherein the first multiplexer circuit includes the first, second, third, and fourth switches; and
in a second mode, the first control circuit is configured to enable the second and fourth switches and disable the first and third switches to connect the first and second rectifier terminals to, respectively, the second power terminal and the reference terminal.

29. The apparatus of claim 28, wherein the first control circuit is configured to set relative durations of the first and second modes based on comparing a voltage at the second power terminal with a first reference voltage on the first reference terminal.

30. The apparatus of claim 27, further comprising a first capacitor coupled to the first power terminal and a second capacitor coupled to the second power terminal.

31. The apparatus of claim 30, wherein the first and second capacitors are external to a packaged integrated circuit.

32. The apparatus of claim 27, further comprising a third capacitor coupled to the third power terminal and a fourth capacitor coupled to the fourth power terminal.

33. The apparatus of claim 32, wherein the third and fourth capacitors are external to a packaged integrated circuit.

34. A method comprising:
in a first mode, connecting first and second inverter terminals of a primary side inverter to, respectively, a first power terminal and a second power terminal;
while in the first mode, switching the primary side inverter to transfer power from a primary side to a secondary side within a first interval;
determining a voltage at the second power terminal;
responsive to the voltage being above a threshold, and after the first interval ends, switching from the first mode to a second mode, in which in the second mode, connecting the first and second inverter terminals to, respectively, the second power terminal and a reference terminal; and
while in the second mode, switching the primary side inverter to transfer power from a primary side to a secondary side within a second interval.

35. The method of claim 34, wherein the threshold is a first threshold, and the method further comprises:
determining the voltage at the second power terminal; and
responsive to the voltage being below a second threshold, and after the second interval ends, switching from the second mode back to the first mode.

36. A method comprising:
in a first mode, connecting first and second rectifier terminals of a second side rectifier to, respectively, a first power terminal and a second power terminal;
while in the first mode, determining a voltage at the second power terminal; and
responsive to the voltage being below a threshold, switching from the first mode to a second mode, in which in the second mode, connecting the first and second rectifier terminals to, respectively, the second power terminal and a reference terminal.

37. The method of claim 36, wherein the threshold is a first threshold, and the method further comprises:
determining the voltage at the second power terminal; and
responsive to the voltage being below a second threshold, switching from the second mode back to the first mode.
